(19) United States
(12) Patent Application Publication
(10) Pub. No.: US 2010/0284433 A1
(43) Pub. Date: Nov. 11, 2010

(54) SEMICONDUCTOR LASER DEVICE AND DISPLAY

(75) Inventors: Masayuki Hata, Takatsuki-shi (JP); Yasumitsu Kunoh, Tottori-shi (JP); Yasuhiko Nomura, Osaka-shi (JP); Saburo Nakashima, Yawata-shi (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi-shi (JP)

(21) Appl. No.: 12/812,715

(22) PCT Filed: Sep. 17, 2009
(86) PCT No.: PCT/JP2009/066226

§ 371 Date: Jul. 13, 2010

(30) Foreign Application Priority Data
Sep. 30, 2008 (JP) 2008-251967
Sep. 30, 2008 (JP) 2008-254553
Nov. 7, 2008 (JP) 2008-286020
Dec. 15, 2008 (JP) 2008-317855
Sep. 16, 2009 (JP) 2009-214291

(51) Int. Cl. H01S 5/40; H01S 5/34; H01S 5/343; H01S 5/026

(52) U.S. Cl. 372/45.011; 372/50.121; 977/755; 977/951

(57) ABSTRACT

A semiconductor laser device capable of easily obtaining a desired hue is obtained. This semiconductor laser device (100) includes a green semiconductor laser element (30) having one or a plurality of laser beam emitting portions, a blue semiconductor laser element (50) having one or a plurality of laser beam emitting portions, and a red semiconductor laser element (10) having one or a plurality of laser beam emitting portions. At least two semiconductor laser elements among the green semiconductor laser element, the blue semiconductor laser element and the red semiconductor laser element have such a relation that the number of the laser beam emitting portions of the semiconductor laser element whose total output power is relatively small is larger than the number of the laser beam emitting portions of the semiconductor laser element, having a plurality of laser beam emitting portions, whose total output power is relatively large, or the number of the semiconductor laser element, having one laser beam emitting portion, whose output power is relatively large.

### TECHNICAL FIELD

The present invention relates to a semiconductor laser device and a display, and more particularly, it relates to a semiconductor laser device and a display each comprising a plurality of semiconductor laser elements.

### BACKGROUND ART

In recent years, a display employing laser beams as light sources has been actively developed. In particular, it is expected to employ semiconductor laser elements as light sources for a miniature display. In this case, further miniaturization of the light sources is enabled by loading semiconductor lasers emitting respective RGB colors on one package.

In general, therefore, a light-emitting device loaded with a red semiconductor laser element, a green semiconductor laser element and a blue semiconductor laser element is proposed in Japanese Patent Laying-Open No. 2001-230502.

Japanese Patent Laying-Open No. 2001-230502 discloses a light-emitting device comprising a first light-emitting element having a laser oscillation portion capable of emitting a beam in the 400 nm band and a second light-emitting element having two laser oscillation portions capable of respective emitting beams of the 500 nm band and the 700 nm band. This light-emitting device is so formed that the first light-emitting element and the second light-emitting element emit a red beam (R), a green beam (G) and a blue beam (B) corresponding to the three primary colors of light, to be utilizable as light sources of a full-color display. In this light-emitting device, each of the laser oscillation portions (light-emitting points) is provided one by one for the oscillation wavebands.

In a full-color display reproducing ideal white light, for example, light output powers of the light-emitting elements are so adjusted that R:G:B=about 2:7:1 when expressed in respective luminous flux (lumen) ratios of the RGB colors. In a case of employing a red beam of about 650 nm, a green beam of about 530 nm and a blue beam of about 480 nm, the beams are so adjusted to R:G:B=about 18.7:8.1:7.1 in terms of laser outputs that ideal white light can be reproduced. In a case of employing a red beam of about 650 nm, a green beam of about 550 nm and a blue beam of about 460 nm, the beams are so adjusted to R:G:B=about 18.7:7:16.7 in terms of laser output powers that ideal white light can be reproduced. Thus, in the full-color display, a large difference is required between output powers required to the respective light-emitting elements in response to the lasing wavelengths of the laser beams. In particular, a larger output power is required to the light-emitting element emitting the red beam than those emitting the green beam and the blue beam.

### PRIOR ART

### Patent Document

Patent Document 1: Japanese Patent Laying-Open No. 2001-230502

### SUMMARY OF THE INVENTION

### Problem to be Solved by the Invention

In the light-emitting device disclosed in the aforementioned Japanese Patent Laying-Open No. 2001-230502, however, each of the laser oscillation portions is provided one by one for the oscillation wavebands (three wavebands of red, green and blue), and hence there is such a problem that, even if it is intended to obtain a desired hue (color mixing) by rendering the output powers of the red, green and blue laser oscillation portions different from each other, it may be impossible to flexibly cope with this.

The present invention has been proposed in order to solve the aforementioned problem, and an object of the present invention is to provide a semiconductor laser device and a display each capable of easily obtaining a desired hue.

### Means for Solving the Problem

In order to attain the aforementioned object, a semiconductor laser device according to a first aspect of the present invention comprises a green semiconductor laser element having one or a plurality of laser beam emitting portions, a blue semiconductor laser element having one or a plurality of laser beam emitting portions, and a red semiconductor laser element having one or a plurality of laser beam emitting portions, while at least two semiconductor laser elements among the green semiconductor laser element, the blue semiconductor laser element and the red semiconductor laser element have such a relation that the number of the laser beam emitting portions of the semiconductor laser element whose total output power is relatively small is larger than the number of the laser beam emitting portions of the semiconductor laser element, having a plurality of laser beam emitting portions, whose total output power is relatively large, or the number of the semiconductor laser element, having one laser beam emitting portion, whose output power is relatively large.

In the semiconductor laser device according to the first aspect of the present invention, as hereinabove described, at least two semiconductor laser elements among the green semiconductor laser element, the blue semiconductor laser element and the red semiconductor laser element are so formed that the number of the laser beam emitting portions of the semiconductor laser element whose total output power is relatively small is larger than the number of the laser beam emitting portions of the semiconductor laser element, having the plurality of laser beam emitting portions, whose total output power is relatively large, or the number of the semiconductor laser element, having one laser beam emitting portion, whose output power is relatively large, whereby the total output powers of the semiconductor laser elements are easily adjusted and the semiconductor laser device can be so formed as to have a desired output power in a case of constituting the semiconductor laser device with reference to the semiconductor laser element whose output power or total output power is large, since the number of individual semiconductor laser elements constituting the laser element is rendered larger in the semiconductor laser element whose total output power is set relatively small. Thus, the semiconductor laser element whose output power (total output power) is relatively large and the semiconductor laser element of a relatively small output power (total output power) whose output power is properly adjusted can be combined with each other, whereby a desired hue can be easily obtained in a case of utilizing the semiconductor laser device as a light source. In a case where it is difficult for the laser elements emitting a green beam and a blue beam to obtain large output powers as compared with the red semiconductor laser element easily obtaining a large output power when obtaining white light with the red, green and blue semiconductor laser elements, for example, the numbers of the green and blue semiconductor laser elements can be rendered larger than the number of the red semiconductor laser element, whereby the output powers of the green and blue semiconductor laser elements can be easily adjusted. Thus, ideal white light can be easily obtained.

Preferably, the aforementioned semiconductor laser device according to the first aspect has a relation of n1>n2>n3, where n1, n2 and n3 represent the numbers of the laser beam emitting portions of the green semiconductor laser element, the blue semiconductor laser element and the red semiconductor laser element respectively. According to this structure, the numbers of laser oscillation portions emitting a blue beam and a green beam can be increased in preference to the number of a laser oscillation portion of the red semiconductor laser element in a case where it is difficult for the laser oscillation portions emitting the green beam and the blue beam to obtain large output powers as compared with the red semiconductor laser element easily obtaining a relatively large output power when obtaining white light with the aforementioned three types of semiconductor laser elements, for example. Thus, the output powers of the green and blue semiconductor laser elements can be easily adjusted, whereby a semiconductor laser device capable of easily obtaining ideal white light can be easily formed.

When the number of the laser beam emitting portions of the green semiconductor laser element or the blue semiconductor laser element is larger than the number of the laser beam emitting portion of the red semiconductor laser element, output powers of the individual laser beam emitting portions in the green or blue semiconductor laser element can be suppressed small, whereby temperature rise of the green semiconductor laser element or the blue semiconductor laser element can be suppressed due to the small output powers of the individual laser beam emitting portions. In addition, the areas of the laser beam emitting portions in the green or blue semiconductor laser element can be increased in response to the number of the laser beam emitting portions, whereby heat generated in the semiconductor laser element can be released through wider surface areas. Thus, deterioration of the green semiconductor laser element or the blue semiconductor laser element is suppressed, whereby the life of the semiconductor laser element can be elongated.

Preferably in the aforementioned semiconductor laser device according to the first aspect, the green semiconductor laser element and the blue semiconductor laser element are formed on a substrate common to the green semiconductor laser element and the blue semiconductor laser element. According to this structure, the green semiconductor laser element and the blue semiconductor element are integrated and formed on the common substrate, whereby the widths of the semiconductor laser elements can be reduced due to the integration as compared with a case where the green semiconductor laser element and the blue semiconductor element emitting beams of different lasing wavelengths are formed on different substrates and thereafter arranged in a package at a prescribed interval. Thus, the integrated semiconductor laser elements can be easily arranged in a package.

Preferably in the aforementioned semiconductor laser device according to the first aspect, the green semiconductor laser element is a monolithic element provided with a plurality of laser beam emitting portions, while the blue semiconductor laser element is a monolithic element provided with a plurality of laser beam emitting portions. According to this structure, the green semiconductor laser element and the blue semiconductor laser element are integrated and formed on the substrate common thereto in response to the lasing wavelengths, whereby the respective widths of the semiconductor laser elements can be reduced due to the integration. Thus, the semiconductor laser elements can be easily arranged in the package in the integrated state also in a case where a large number of semiconductor laser elements are required.

Preferably in the aforementioned semiconductor laser device according to the first aspect, the red semiconductor laser element is bonded to at least either the green semiconductor laser element or the blue semiconductor laser element. According to this structure, the laser beam emitting portions of the respective laser elements can be parallelly arranged and rendered close to each other also in a bond direction for the laser elements as compared with a case where the green semiconductor laser element, which is formed by increasing the number of the laser beam emitting portions transversely in line since the required number is the largest, the red semiconductor laser element and the blue semiconductor laser element are arranged in a linear manner (in a transverse in-line direction, for example), whereby the semiconductor laser elements can be so arranged that the plurality of laser beam emitting portions concentrate on a central region of the package. Thus, a plurality of laser beams emitted from the semiconductor laser device can be rendered close to an optical axis of an optical system, whereby the semiconductor laser device and the optical system can be easily adjusted.

Preferably, the aforementioned semiconductor laser device according to the first aspect further comprises a base to which the green semiconductor laser element, the blue semiconductor laser element and the red semiconductor laser element are bonded and a plurality of terminals electrically connected with an external portion and insulated from each other, the green semiconductor laser element includes electrodes formed on a surface opposite to the base, at least two electrodes of the green semiconductor laser element among the n1 laser beam emitting portions are connected to different terminals, where n1 represents the number of the laser beam emitting portions of the green semiconductor laser element. According to this structure, the green semiconductor laser element having a larger number of laser beam emitting portions than the red semiconductor laser element and the blue semiconductor laser element can be individually driven in response to the number of the laser beam emitting portions, whereby the output power of the green semiconductor laser element can be easily adjusted in response to the required total output power.

Preferably in the aforementioned structure in which the green semiconductor laser element and the blue semiconductor laser element are formed on the common substrate, the green semiconductor laser element includes a first active layer formed on the surface of the substrate and having a major surface of a semipolar plane, the blue semiconductor laser element includes a second active layer formed on the surface of the substrate and having a major surface of a surface orientation substantially identical to the semipolar plane, and the first active layer includes a first well layer having a compressive strain and having a thickness of at least 3 nm while the second active layer includes a second well layer having a compressive strain. The “green semiconductor laser element” denotes a semiconductor laser element whose lasing wavelength is in the range of at least about 500 nm and not more than about 565 nm. The “thickness” in the present invention is the thickness of a single well layer when a quantum well structure of an active layer has a single quantum well (SQW) structure, and denotes the thickness of each well layer of multiple well layers constituting an MQW structure when the quantum well structure of the active layer has a multiple quantum well (MQW) structure. The compressive strain denotes a strain resulting from compressive force generated due to a difference in lattice constant between an underlayer and the well layer. The compressive strain is caused in a case where the well layer is grown in pseudo-lattice-matching with the substrate in a state where the in-plane lattice constant of the well layer in an unstrained state is large as compared with the in-plane lattice constant of the substrate in an unstrained state, or in a case where the well layer is grown in pseudo-lattice-matching on a layer (a cladding layer or a barrier layer) having an in-plane lattice constant small as compared with the in-plane lattice constant of the unstrained well layer, for example. According to this structure, an extensional direction of a waveguide in which an optical gain of the blue semiconductor laser element is maximized and an extensional direction of a waveguide in which an optical gain of the green semiconductor laser element is maximized can be substantially agreed with each other in a case of forming the green semiconductor laser element including the first active layer having the major surface of the semipolar plane and the blue semiconductor laser element including the second active layer having the major surface of the semipolar plane on the surface of the same substrate.

Preferably in this case, the first well layer is made of InGaN. According to this structure, a green semiconductor laser element having higher efficiency can be prepared.

Preferably in the aforementioned structure in which the first active layer includes the first well layer having the compressive strain and the second active layer includes the second well layer having the compressive strain, the second well layer is made of InGaN. According to this structure, a blue semiconductor laser element having higher efficiency can be prepared.

Preferably in the aforementioned structure in which the first active layer includes the first well layer having the compressive strain and the second active layer includes the second well layer having the compressive strain, the thickness of the first well layer is larger than the thickness of the second well layer. In the green semiconductor laser element including the first active layer having the major surface of the semipolar plane and the blue semiconductor laser element including the second active layer having the major surface of the semipolar plane, it is conceivable that a change in the extensional direction of the waveguide in which the optical gain is maximized is harder to cause in the blue semiconductor laser element in which the compressive strain in the active layer is smaller and the lasing wavelength is shorter than the green semiconductor laser element, whereby the thickness of the second well layer of the second active layer of the blue semiconductor laser element can be rendered smaller than the thickness of the first well layer of the first active layer of the green semiconductor laser element. Thus, formation of a misfit dislocation resulting from a difference between the lattice constants of a crystal lattice of the second well layer and a crystal lattice of an under layer on which the second well layer is grown can be suppressed in the second active layer of the blue semiconductor laser element.

Preferably in the aforementioned structure in which the first active layer includes the first well layer having the compressive strain and the second active layer includes the second well layer having the compressive strain, the semipolar plane is a plane inclined by at least about 10 degrees and not more than about 70 degrees with respect to a (0001) plane or a (000-1) plane. According to this structure, the extensional directions of the waveguides in which the optical gains are maximized can be more reliably substantially ed with each other in the green semiconductor laser element and the blue semiconductor laser element.

Preferably in the aforementioned structure in which the first active layer includes the first well layer having the compressive strain and the second active layer includes the second well layer having the compressive strain, the blue semiconductor laser element and the green semiconductor laser element further include waveguides extending in a direction projecting a [0001] direction on the major surface of the semipolar plane respectively. In order to maximize the optical gains of the semiconductor laser elements, it is required to form the waveguides perpendicularly to principal polarization directions of the beams emitted from the active layers. In other words, the waveguides are so formed in the direction obtained by projecting the [0001] direction onto the major surface of the semipolar plane that the optical gains of the blue semiconductor laser element and the green semiconductor laser element can be maximized while the blue beam of the blue semiconductor laser element and the green beam of the green semiconductor laser element can be emitted from a cavity facet on a common plane.

Preferably in the aforementioned structure in which the green semiconductor laser element and the blue semiconductor laser element are formed on the common substrate, the blue semiconductor laser element includes a third active layer made of a nitride-based semiconductor formed on the surface of the substrate and having a major surface of a nonpolar plane, and the green semiconductor laser element includes a fourth active layer made of a nitride-based semiconductor formed on the surface of the substrate and having a major surface of a surface orientation substantially identical to the nonpolar plane. In the present invention, “nonpolar plane” is a wide concept including all crystal planes other than a c-plane ((0001) plane) which is a polar plane, and includes non-polar planes of (H,K,−H−K,0) planes such as an m-plane ((1-100) plane) and an a-plane ((11-20) plane) and a plane (semipolar plane) inclined from the c-plane ((0001) plane). According to this structure, piezoelectric fields generated in the first active layer and the second active layer can be reduced as compared with a case of having major surfaces of c-planes which are polar planes. Thus, inclinations of energy bands in the first well layer of the first active layer and the second well layer of the second active layer resulting from the piezoelectric fields can be reduced, whereby the quantities of changes (fluctuation widths) in the lasing wavelengths of the blue semiconductor laser element and the green semiconductor laser element can be more reduced. Consequently, reduction in the yield of the integrated semiconductor laser device comprising the blue semiconductor laser element and the green semiconductor laser element formed on the surface of the same substrate can be suppressed.

Preferably in this case, the third active layer has a quantum well structure having a third well layer made of InGaN while the fourth active layer has a quantum well structure having a fourth well layer made of InGaN, and the thickness of the third well layer is larger than the thickness of the fourth well layer. According to this structure, the lasing wavelengths of the blue semiconductor laser element and the green semiconductor laser element are shifted toward shorter-wavelength sides than the peak wavelengths thereof as compared with a case where the laser elements are formed on c-planes ((0001) planes), since influences by piezoelectric fields are small on the nonpolar planes. Thus, in order to shift the lasing wavelengths of the blue semiconductor laser element and the green semiconductor laser element to longer-wavelength sides, it is necessary to render In compositions in the third well layer of the blue semiconductor laser element and the fourth well layer of the green semiconductor laser element larger than the case where the elements are formed on c-planes. When forming the third well layer and the fourth well layer made of InGaN, further, it is necessary to render the In composition in the fourth well layer of the green semiconductor laser element large as compared with the third well layer of the blue semiconductor laser element, since the lasing wavelength of the green semiconductor laser element is long as compared with the lasing wavelength of the blue semiconductor laser element. Thus, when the In compositions are rendered larger, lattice constants in the planes of the third well layer and the fourth well layer are rendered larger than lattice constants of crystal lattices of planes on which the third well layer and the fourth well layer are grown, and hence compressive strains in the planes of the third well layer and the fourth well layer are larger, and misfit dislocations are easily formed in the third well layer and the fourth well layer. Further, the fourth well layer of the green semiconductor laser element has a larger compressive strain than the third well layer of the blue semiconductor laser element, and easily causes crystal defects. In this case, the thickness of the fourth well layer easily causing crystal defects due to the large In composition can be reduced by rendering the thickness of the third well layer of the third active layer of the blue semiconductor laser element larger than the thickness of the fourth well layer of the fourth active layer of the green semiconductor laser element, whereby formation of crystal defects can be suppressed in the fourth active layer of the green semiconductor laser element.

Preferably in the aforementioned structure in which the green semiconductor laser element includes the third active layer and the blue semiconductor laser element includes the fourth active layer, the nonpolar plane is a substantially (11-22) plane. According to this structure, the quantities of changes in the lasing wavelengths of the blue semiconductor laser element and the green semiconductor laser element can be reduced since the substantially (11-22) plane has a smaller piezoelectric field as compared with other semipolar planes.

Preferably in the aforementioned structure in which the green semiconductor laser element includes the third active layer and the blue semiconductor laser element includes the fourth active layer, the major surface of the substrate has a surface orientation substantially identical to the nonpolar plane. According to this structure, the blue semiconductor laser element including the third active layer having the major surface of the nonpolar plane and the green semiconductor laser element including the fourth active layer having the major surface of the nonpolar plane can be easily formed by simply growing semiconductor layers on the substrate having the major surface of the surface orientation of the nonpolar plane substantially identical to the third active layer of the blue semiconductor laser element and the fourth active layer of the green semiconductor laser element.

Preferably in the aforementioned structure in which the green semiconductor laser element and the blue semiconductor laser element are formed on the common substrate, the blue semiconductor laser element is formed on a surface of one side of the substrate and constituted of a fifth active layer, a first semiconductor layer and a first electrode successively stacked from the side of the substrate, the green semiconductor laser element is so formed as to adjacently align with the blue semiconductor laser element and constituted of a sixth active layer, a second semiconductor layer and a second electrode successively stacked from the side of the substrate, the semiconductor laser device further comprises a support base formed on the first electrode through a first fusion layer and formed on the second electrode through a second fusion layer, the substrate has a surface of another side on a side opposite to one side, and the semiconductor laser device has a relation of t3>t4 when t1<t2 and has a relation of t3<t4 when t1>t2 assuming that t1 represents the thickness of the blue semiconductor laser element from the surface of another side to a surface of the first semiconductor layer on one side, t2 represents the thickness of the green semiconductor laser element from the surface of another side to a surface of the second semiconductor layer on one side, t3 represents the thickness of the first electrode and t4 represents the thickness of the second electrode. According to this structure, a difference between the thickness (t1+t3) of the blue semiconductor laser element including the first electrode and the thickness (t2+t4) of the green semiconductor laser element including the second electrode can be further reduced by properly adjusting the thickness t3 of the first electrode and the thickness t4 of the second electrode even if a difference is caused between the thickness t1 of the blue semiconductor laser element from the surface of the other side of the substrate to the surface of the first semiconductor layer on the one side and the thickness t2 of the green semiconductor laser element from the surface of the other side of the substrate to the surface of the second semiconductor layer on the one side. In other words, even if the difference is caused between the thicknesses t1 and t2 of the blue semiconductor laser element and the green semiconductor laser element from the substrate to the first semiconductor layer and the second semiconductor layer respectively, the difference (difference between the thickness t1 and the thickness t2) can be adjusted through the difference (difference between t3 and t4) between the thicknesses of the first electrode and the second electrode. Thus, the thicknesses of the blue semiconductor laser element and the green semiconductor laser element including the common substrate can be uniformized, and hence it is unnecessary to make the fusion layers absorb the difference between the thicknesses of the semiconductor laser elements when bonding this semiconductor laser device to the support base through the fusion layers (the first fusion layer and the second fusion layer) by a junction-down system or the like, whereby the fusion layers can be suppressed to the minimum necessary quantities. Consequently, such an inconvenience is suppressed that an electrical short circuit is caused between the laser elements due to excessive fusion layers jutting out after bonding, whereby the yield in formation of the semiconductor laser elements can be improved.

Preferably in this case, the support base is a submount. According to this structure, the used fusion layers can be suppressed to the respective minimum necessary quantities in the two semiconductor laser elements when bonding this semiconductor laser device to the submount through the fusion layers (the first fusion layer and the second fusion layer) by the junction-down system. Thus, a semiconductor laser device whose yield improves can be easily formed.

Preferably in the aforementioned structure in which the blue semiconductor laser element has the first electrode and the green semiconductor laser element has the second electrode, the first electrode consists of a first pad electrode, and the second electrode consists of a second pad electrode. According to this structure, the thicknesses of the blue semiconductor laser element and the green semiconductor laser element formed on the surface of the common substrate on one side can be easily uniformized by properly adjusting the thicknesses of the first pad electrode and the second pad electrode respectively.

Preferably in this case, the thickness of the first pad electrode is larger than the thickness of the second pad electrode in a case of t3>t4, and the thickness of the second pad electrode is larger than the thickness of the first pad electrode in a case of t3<t4. According to this structure, the thicknesses of the blue semiconductor laser element and the green semiconductor laser element formed on the surface of the common substrate on one side are uniformized by adjusting the thicknesses of the first pad electrode and the second pad electrode in response to the aforementioned conditions respectively, whereby the used fusion layers can be suppressed to the respective minimum necessary quantities in the two semiconductor laser elements when bonding this semiconductor laser device to the submount through the fusion layers in the junction-down system.

A display according to a second aspect of the present invention comprises a semiconductor laser device including a red semiconductor laser element having one or a plurality of laser beam emitting portions, a green semiconductor laser element having one or a plurality of laser beam emitting portions, and a blue semiconductor laser element having one or a plurality of laser beam emitting portions, in which at least two semiconductor laser elements among the red semiconductor laser element, the green semiconductor laser element and the blue semiconductor laser element have such a relation that the number of the laser beam emitting portions of the semiconductor laser element emitting a relatively long wavelength is larger than the number of the laser beam emitting portions of the semiconductor laser element emitting a relatively short wavelength, and modulation means modulating beams from the semiconductor laser device.

In the display according to the second aspect of the present invention, as hereinabove described, at least two semiconductor laser elements among the green semiconductor laser element, the blue semiconductor laser element and the red semiconductor laser element are so formed that the number of the laser beam emitting portions of the semiconductor laser element whose total output power is relatively small is larger than the number of the laser beam emitting portions of the semiconductor laser element, having a plurality of laser beam emitting portions, whose total output power is relatively large, or the number of the semiconductor laser element, having one laser beam emitting portion, whose output power is relatively large, whereby the total output powers of the semiconductor laser elements are easily adjusted and the semiconductor laser device can be so formed as to have a desired output power in a case of constituting the semiconductor laser device with reference to the semiconductor laser element whose output power or total output power is large, since the number of individual semiconductor laser elements constituting the laser element is rendered larger in the semiconductor laser element whose total output power is set relatively small. Thus, the semiconductor laser element whose output power (total output power) is relatively large and the semiconductor laser element of a relatively small output power (total output power) whose output power is properly adjusted can be combined with each other, whereby a desired hue can be easily obtained in a case of utilizing the semiconductor laser device as a light source. In a case where it is difficult for the laser elements emitting a green beam and a blue beam to obtain large output powers as compared with the red semiconductor laser element easily obtaining a large output power when obtaining white light with the semiconductor laser elements of red, green and blue, for example, the numbers of the green and blue semiconductor laser elements can be rendered larger than the number of the red semiconductor laser element, whereby the output powers of the green and blue semiconductor laser elements can be easily adjusted. Thus, a semiconductor laser device capable of easily obtaining ideal white light can be obtained.

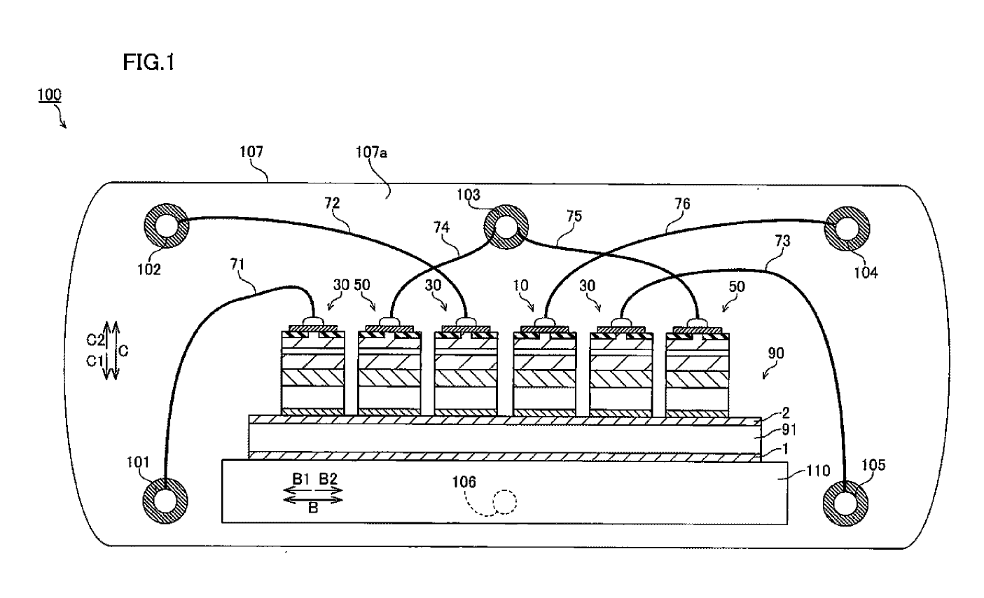

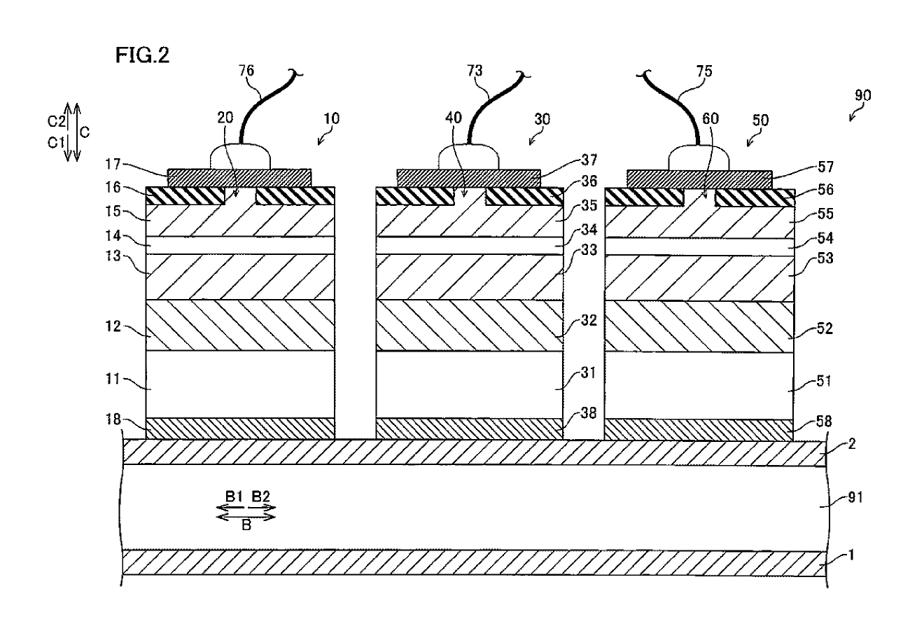

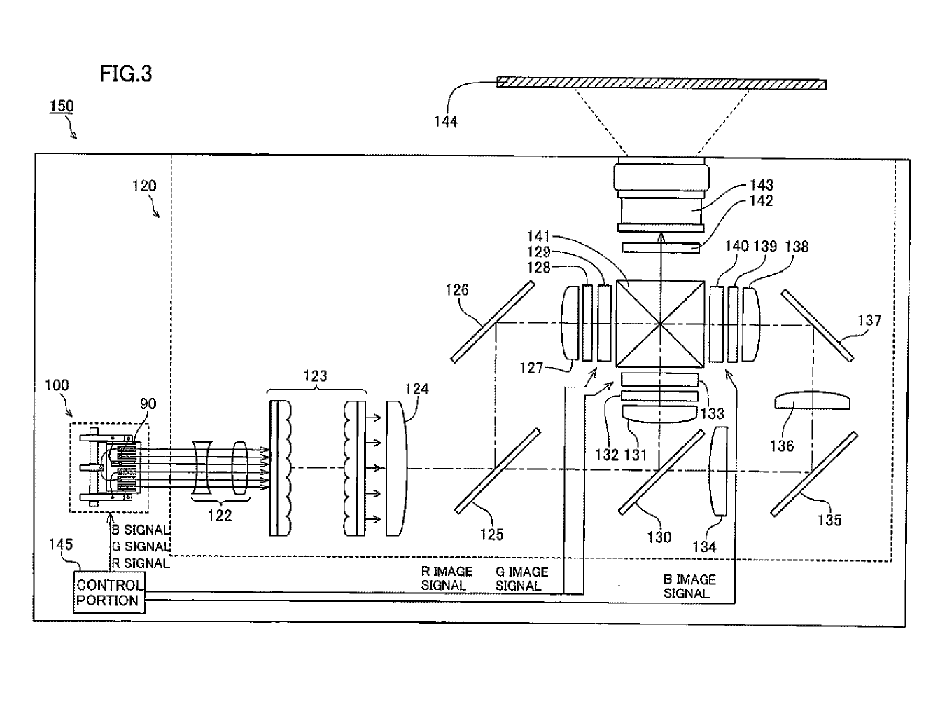

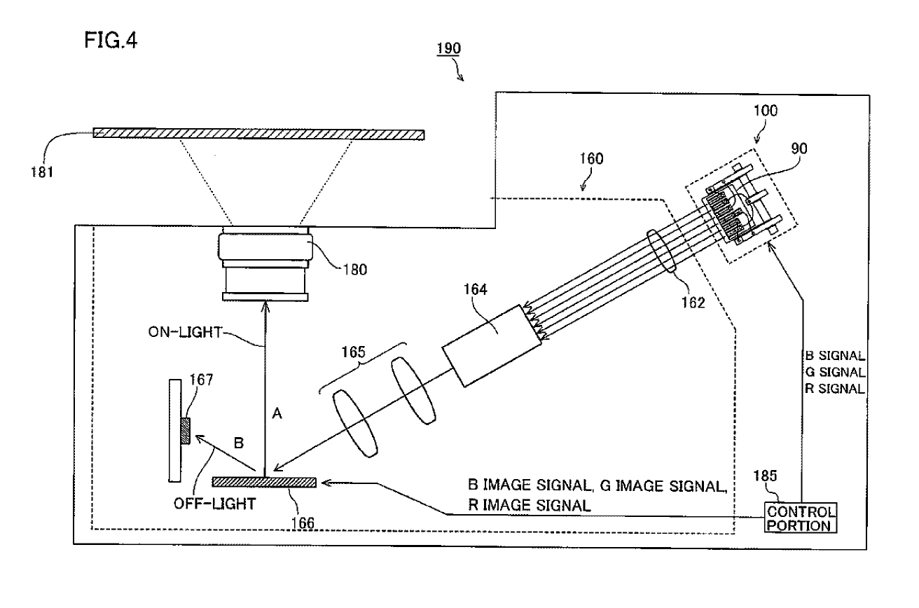

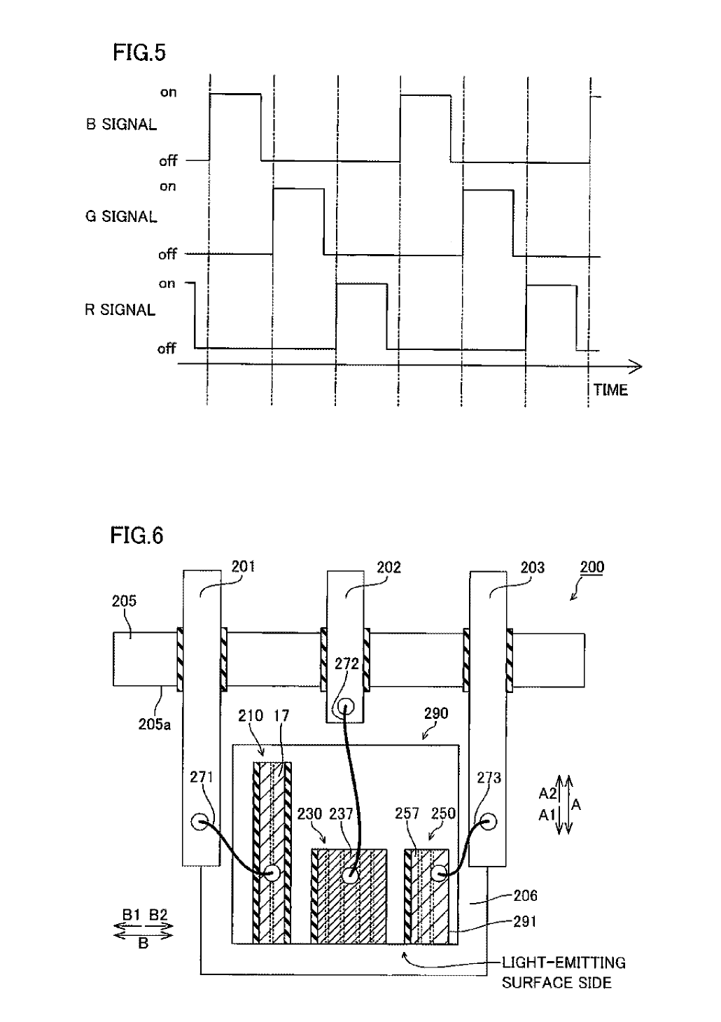

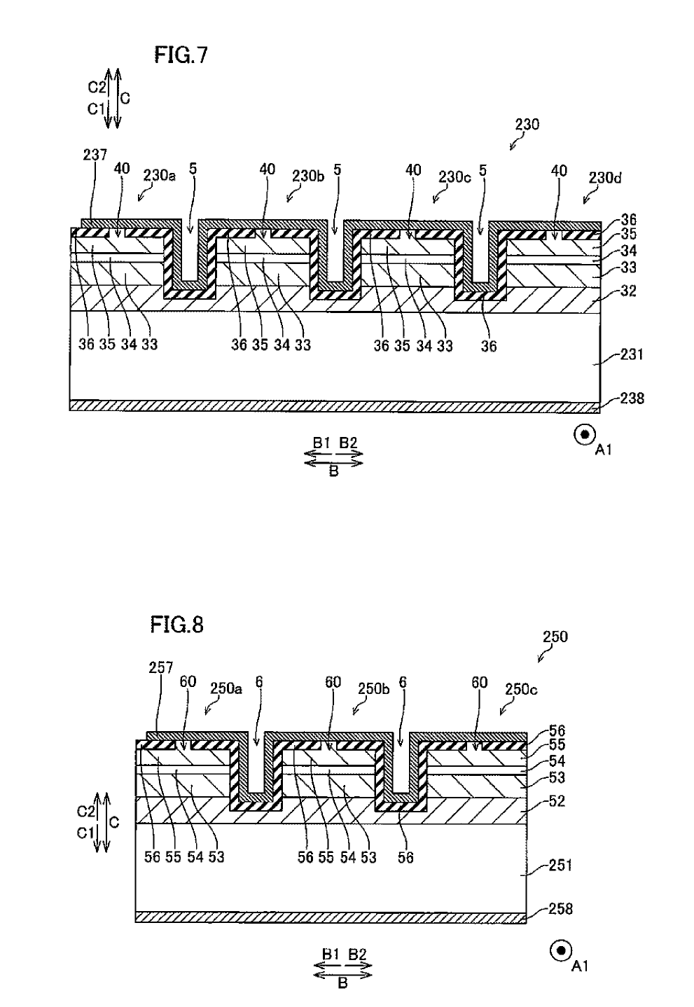

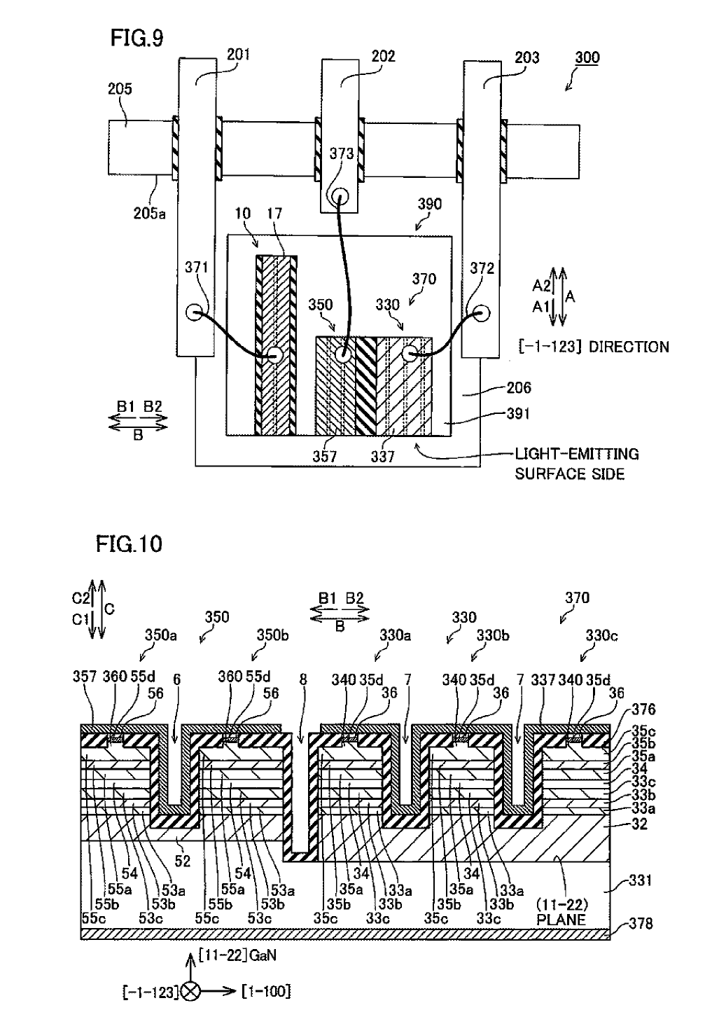

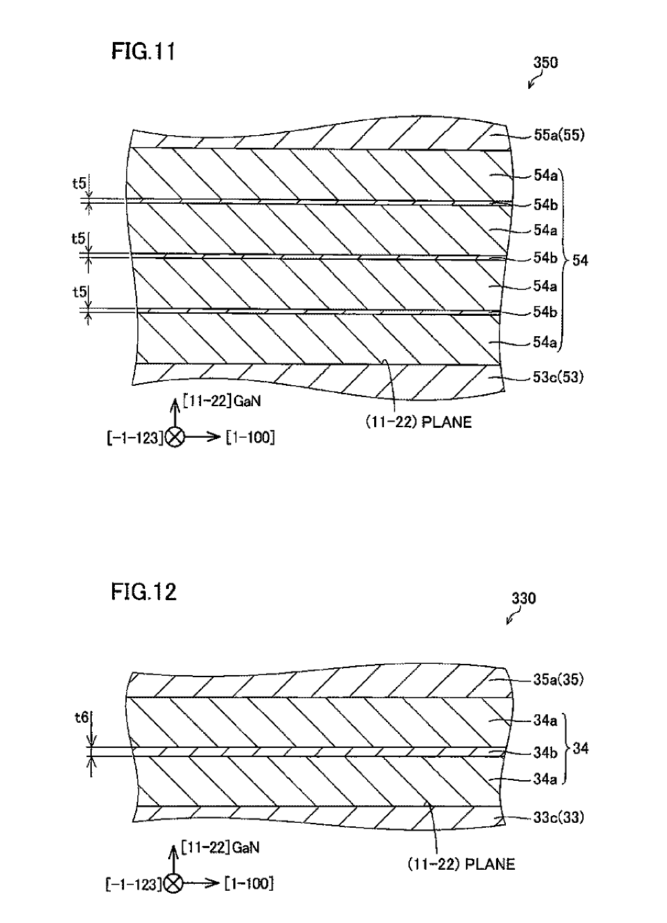

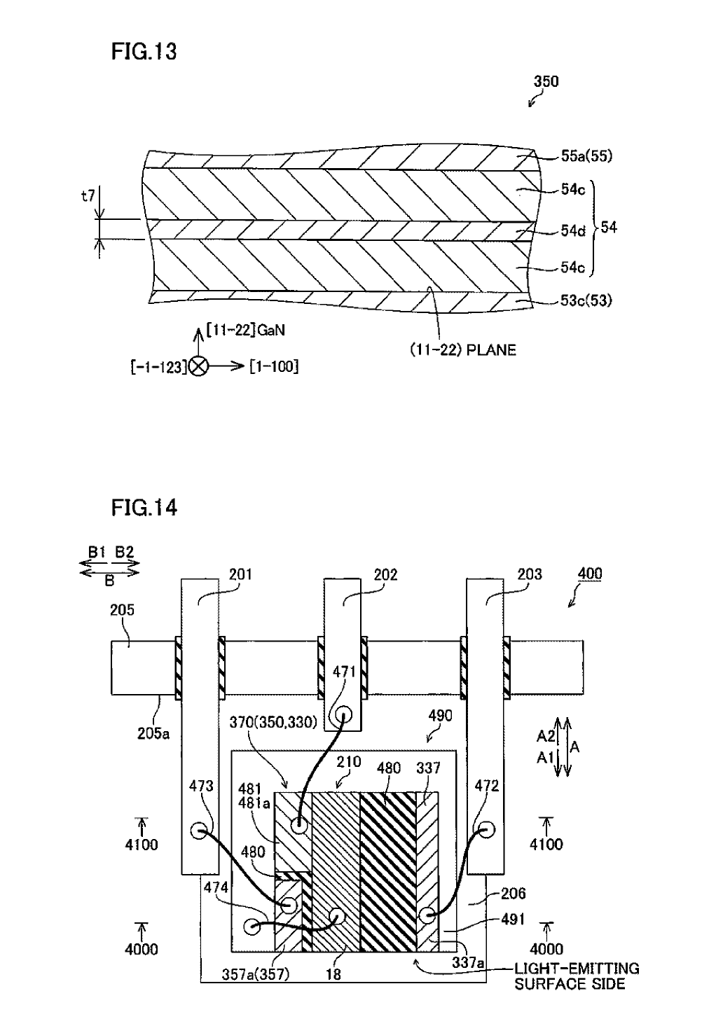

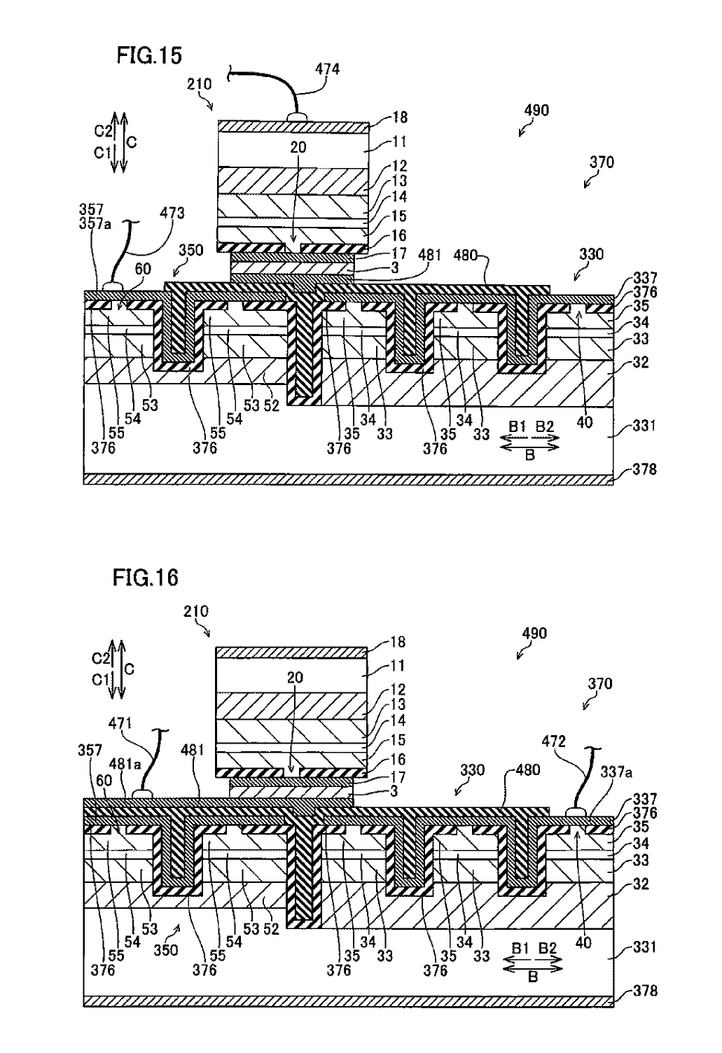

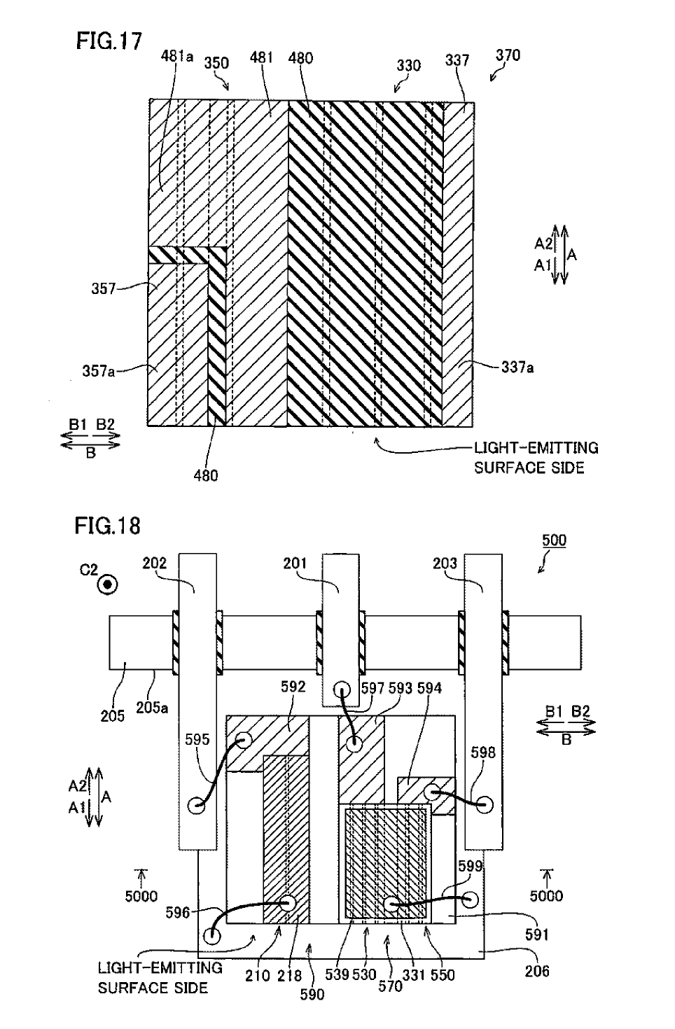

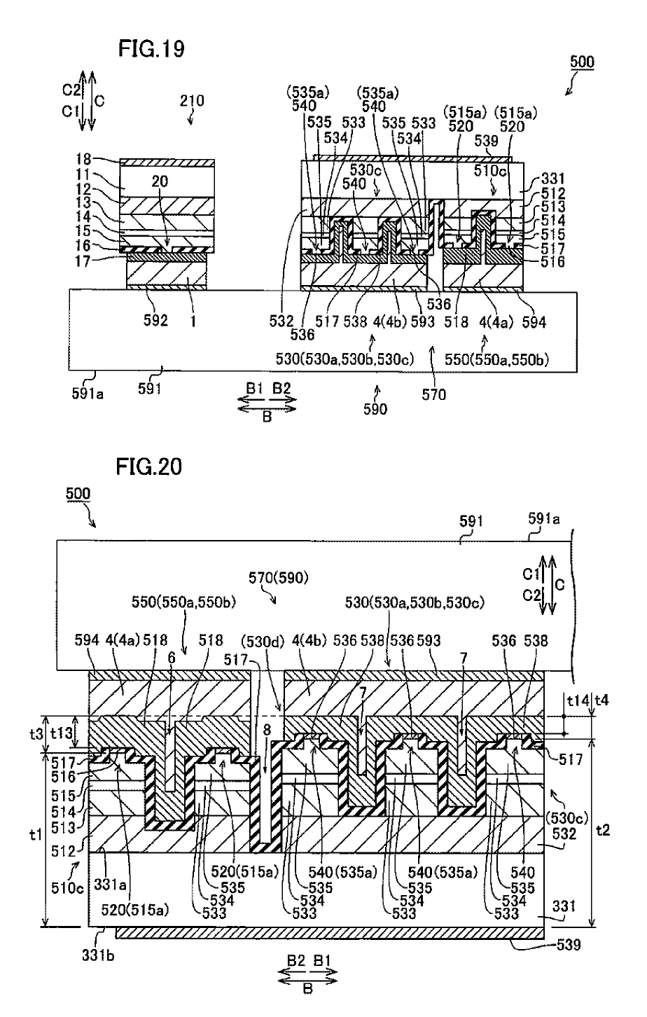

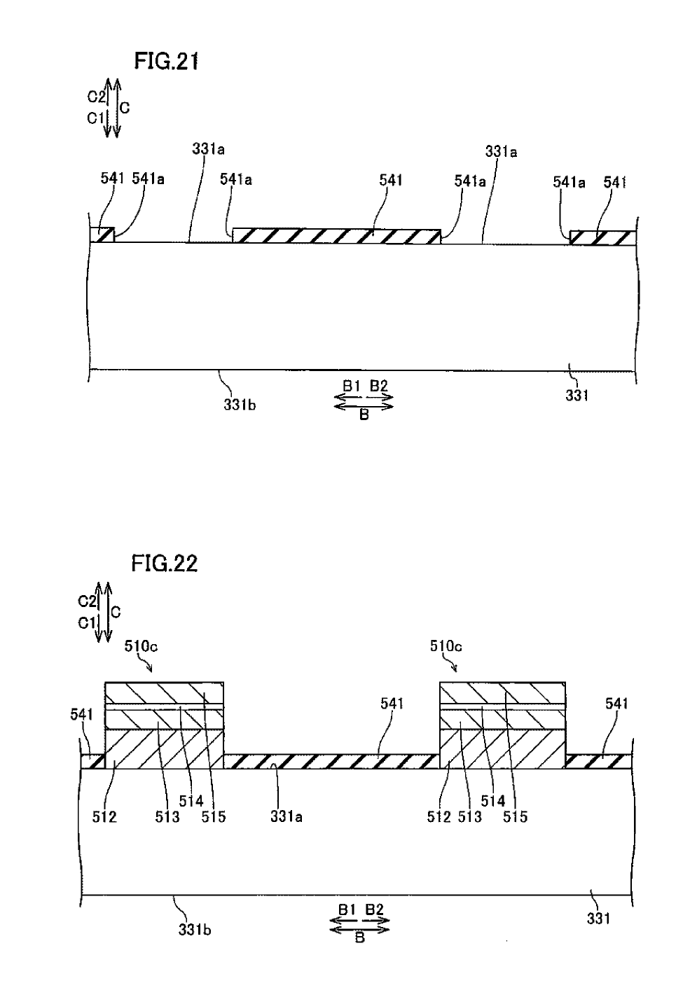

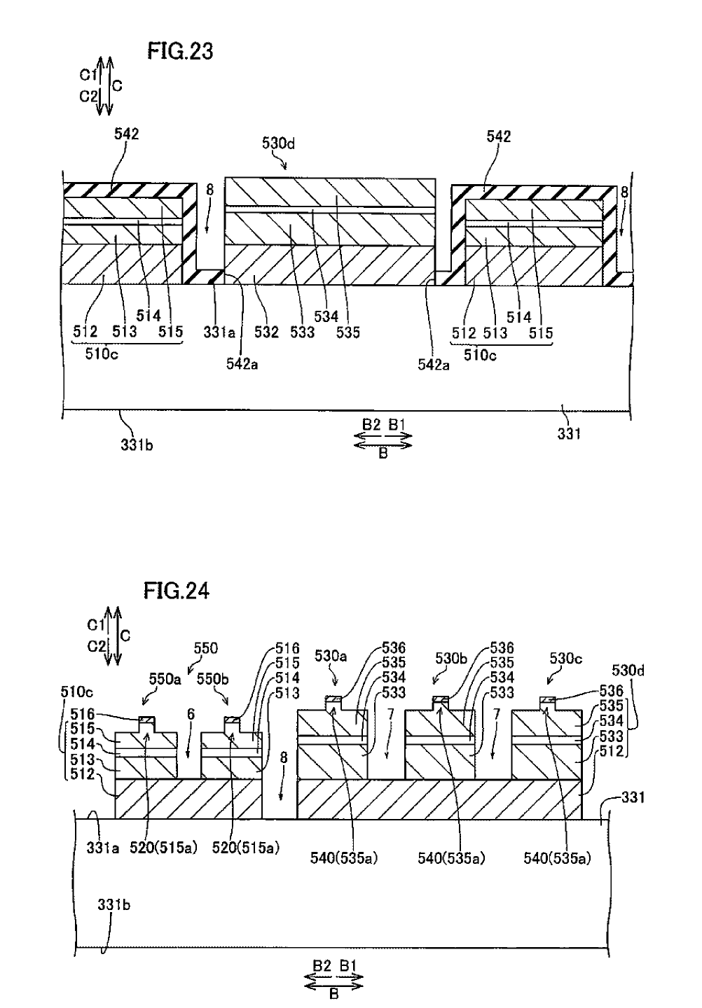

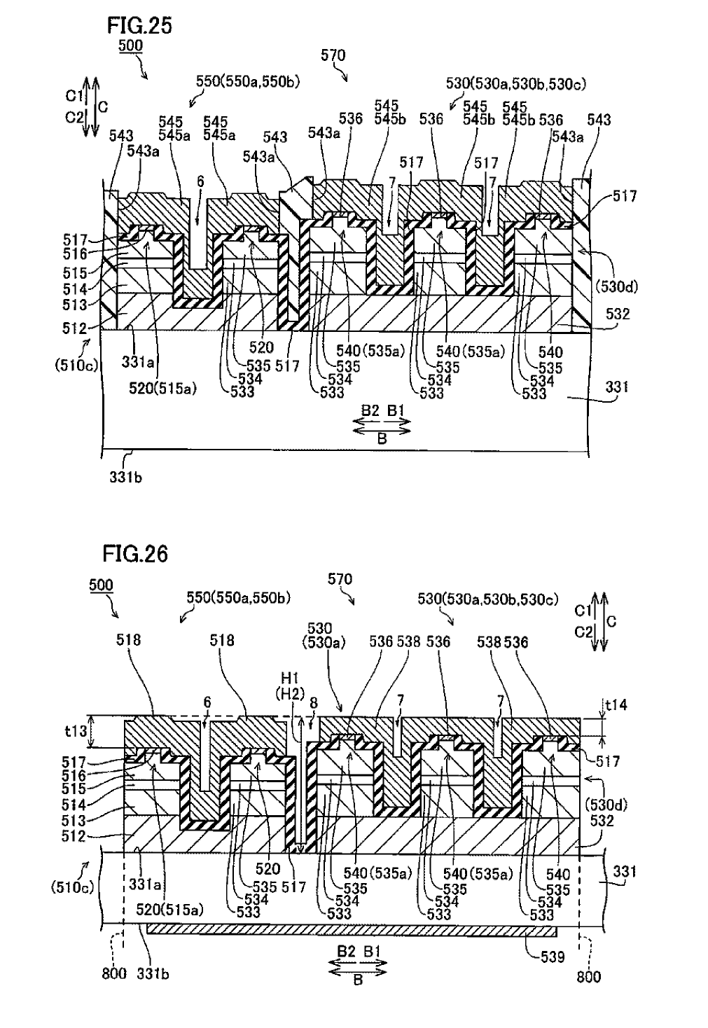

### BRIEF DESCRIPTION OF THE DRAWINGS

[FIG. 1] A front elevational view showing the structure of a semiconductor laser device according to a first embodiment of the present invention.

[FIG. 2] A sectional view showing a detailed structure of the semiconductor laser device according to the first embodiment of the present invention.

[FIG. 3] A block diagram of a projector according to an example loaded with the semiconductor laser device according to the first embodiment of the present invention.

[FIG. 4] A block diagram of a projector according to another example loaded with the semiconductor laser device according to the first embodiment of the present invention.

[FIG. 5] A timing chart showing a state where a control portion in the projector according to another example loaded with the semiconductor laser device according to the first embodiment of the present invention transmits signals in a time-series manner.

[FIG. 6] A plan view showing the structure of a semiconductor laser device according to a second embodiment of the present invention.

[FIG. 7] A sectional view showing the structure of the semiconductor laser device according to the second embodiment of the present invention.

[FIG. 8] A sectional view showing the structure of the semiconductor laser device according to the second embodiment of the present invention.

[FIG. 9] A plan view showing the structure of a semiconductor laser device according to a third embodiment of the present invention.

[FIG. 10] A sectional view showing the structure of the semiconductor laser device according to the third embodiment of the present invention.

[FIG. 11] A sectional view showing the structure of an active layer of a blue semiconductor laser element constituting the semiconductor laser device according to the third embodiment of the present invention.

[FIG. 12] A sectional view showing the structure of an active layer of a green semiconductor laser element constituting the semiconductor laser device according to the third embodiment of the present invention.

[FIG. 13] A sectional view showing the structure of an active layer of a blue semiconductor laser element constituting a semiconductor laser device according to a modification of the third embodiment of the present invention.

[FIG. 14] A plan view showing the structure of a semiconductor laser device according to a fourth embodiment of the present invention.

[FIG. 15] A sectional view showing the structure of the semiconductor laser device according to the fourth embodiment of the present invention.

[FIG. 16] A sectional view showing the structure of the semiconductor laser device according to the fourth embodiment of the present invention.

[FIG. 17] A plan view showing the structure of the semiconductor laser device according to the fourth embodiment of the present invention.

[FIG. 18] A top plan view showing the structure of a semiconductor laser device according to a fifth embodiment of the present invention.

[FIG. 19] A sectional view taken along the line 5000-5000 in FIG. 18.

[FIG. 20] A sectional view showing the structure of a two-wavelength semiconductor laser element portion constituting the semiconductor laser device according to the fifth embodiment of the present invention.

[FIG. 21] A diagram for illustrating a manufacturing process for the semiconductor laser device according to the fifth embodiment of the present invention.

[FIG. 22] A diagram for illustrating the manufacturing process for the semiconductor laser device according to the fifth embodiment of the present invention.

[FIG. 23] A diagram for illustrating the manufacturing process for the semiconductor laser device according to the fifth embodiment of the present invention.

[FIG. 24] A diagram for illustrating the manufacturing process for the semiconductor laser device according to the fifth embodiment of the present invention.

[FIG. 25] A diagram for illustrating the manufacturing process for the semiconductor laser device according to the fifth embodiment of the present invention.

[FIG. 26] A diagram for illustrating the manufacturing process for the semiconductor laser device according to the fifth embodiment of the present invention.

### MODES FOR CARRYING OUT THE INVENTION

Embodiments of the present invention are now described with reference to the drawings.

### First Embodiment

First, the structure of a semiconductor laser device 100 according to a first embodiment of the present invention is described with reference to FIGS. 1 and 2.

In the semiconductor laser device 100 according to the first embodiment of the present invention, an RGB three-wavelength semiconductor laser element portion 90 is fixed onto the upper surface (surface on a C2 side) of a protruding block 110 through a conductive adhesive layer 1 of AuSn solder or the like, as shown in FIG. 1. In the RGB three-wavelength semiconductor laser element portion 90, a red semiconductor laser element 10 having an lasing wavelength of about 655 nm, green semiconductor laser elements 30 each having an lasing wavelength of about 530 nm and blue semiconductor laser elements 50 each having a wavelength of about 460 nm are fixed onto the upper surface of a base 91 through a conductive adhesive layer 2 of AuSn solder or the like at prescribed intervals, so that laser beams of respective colors are substantially parallel to each other and emitted in a front direction of the semiconductor laser device 100.

One red semiconductor laser element 10 has a rated output power of about 800 mW, while one green semiconductor laser element 30 has a rated output power of about 90 mW. One blue semiconductor laser element 50 has a rated output power of about 300 mW.

In order to obtain white light with a red beam of 655 nm, a green beam of 530 nm and a blue beam of 460 nm, it is required to adjust output power ratios of the aforementioned three types of semiconductor laser elements in terms of watts in the RGB three-wavelength semiconductor laser element portion 90 to red:green:blue 24.5:8.1:16.7 (corresponding to red beam:green beam:blue beam=2:7:1 in luminous flux (lumen) ratios).

Therefore, the RGB three-wavelength semiconductor laser element portion 90 is constituted of three green semiconductor laser elements 30, two blue semiconductor laser elements 50 and one red semiconductor laser element 10, as shown in FIG. 1. In other words, the number n1 of the green semiconductor laser elements 30 whose total output power is relatively small is rendered larger (n1 n2) than the number n2 of the blue semiconductor laser elements 50 whose total output power is relatively large, when comparing the number n1 of the green semiconductor laser elements 30 and the number n2 of the blue semiconductor laser elements 50 with each other. Also when comparing the number n1 of the green semiconductor laser elements 30 and the number n3 of the red semiconductor laser element 10, the number n1 of the green semiconductor laser elements 30 whose total output power is relatively small is rendered larger (n1>n3) than the number n3 of the red semiconductor laser element 50 whose total output power is relatively large.

According to the first embodiment, the semiconductor laser elements of the respective colors are arranged to line up in order of green, blue, green, red, green and blue from one side end portion (B1 side) toward the other side end portion (B2 side) as viewed from the side of the front surface (emitting direction of the laser beams of the respective colors) of the semiconductor laser device 100, as shown in FIG. 1. Thus, the green semiconductor laser elements 30, whose number is the largest, are arranged on both sides of the red semiconductor laser element 10 and the blue semiconductor laser elements 50 in the RGB three-wavelength semiconductor laser element portion 90 in a direction (direction B) where the semiconductor laser elements of the respective colors are arrayed, whereby the semiconductor laser device 100 is so formed that white light in a state where green beams having three light-emitting points (laser beam emitting portions), blue beams having two light-emitting points and a red beam of one light-emitting point are properly mixed is obtained.

In the red semiconductor laser element 10, an n-type contact layer 12 made of Si-doped GaAs, an n-type cladding layer 13 made of Si-doped AlGaInP, an MQW active layer 14 in which AlGaInP barrier layers and GaInP well layers are alternately stacked and a p-type cladding layer 15 made of Zn-doped AlGaInP are formed on the upper surface of an n-type GaAs substrate 11, as shown in FIG. 2.

The p-type cladding layer 15 has a projecting portion extending in a striped manner along the emitting direction of the laser beams and planar portions extending on both sides (direction B) of the projecting portion. A ridge 20 of about 2.5 μm in width for constituting a waveguide is formed by the projecting portion of this p-type cladding layer 15. A current blocking layer 16 made of SiO₂ is formed to cover the upper surface of the p-type cladding layer 15 other than the ridge 20. A p-side pad electrode 17 made of Au or the like is formed to cover the upper surfaces of the ridge 20 and the current blocking layer 16. An n-side electrode 18 in which an AuGe layer, an Ni layer and an Au layer are successively stacked from the side closer to the n-type GaAs substrate 11 is formed on the lower surface (surface on a C1 side) of the n-type GaAs substrate 11.

In each green semiconductor laser element 30, an n-type GaN layer 32 made of Ge-doped GaN, an n-type cladding layer 33 made of n-type AlGaN, an MQW active layer 34 in which quantum well layers and barrier layers made of InGaN are alternately stacked, and a p-type cladding layer 35 made of p-type AlGaN are formed on the upper surface of an n-type GaN substrate 31, as shown in FIG. 2.

The p-type cladding layer 35 has a projecting portion extending in a striped manner along the emitting direction of the laser beams and planar portions extending on both sides (direction B) of the projecting portion. A ridge 40 of about 2 μm in width for constituting a waveguide is formed by the projecting portion of this p-type cladding layer 35. A current blocking layer 36 made of SiO₂ is formed to cover the upper surface of the p-type cladding layer 35 other than the ridge 40. A p-side pad electrode 37 made of Au or the like is formed to cover the upper surfaces of the ridge 40 and the current blocking layer 36. An n-side electrode 38 in which a Ti layer, a Pt layer and an Au layer are successively stacked from the side closer to the n-type GaAs substrate 31 is formed on the lower surface of the n-type GaAs substrate 31.

In each blue semiconductor laser element 50, an n-type GaN layer 52 made of Ge-doped GaN, an n-type cladding layer 53 made of n-type AlGaN, an MQW active layer 54 in which quantum well layers and barrier layers made of InGaN are alternately stacked, and a p-type cladding layer 55 made of p-type AlGaN are formed on the upper surface of an n-type GaN substrate 51, as shown in FIG. 2.

The p-type cladding layer 55 has a projecting portion extending in a striped manner along the emitting direction of the laser beams and planar portions extending on both sides (direction B) of the projecting portion. A ridge 60 of about 1.7 μm in width for constituting a waveguide is formed by the projecting portion of this p-type cladding layer 55. A current blocking layer 56 made of SiO₂ is formed to cover the upper surface of the p-type cladding layer 55 other than the ridge 60. A p-side pad electrode 57 consisting of an Au layer or the like is formed to cover the upper surfaces of the ridge 60 and the current blocking layer 56. An n-side electrode 58 in which a Ti layer, a Pt layer and an Au layer are successively stacked from the side closer to the n-type GaAs substrate 51 is formed on the lower surface of the n-type GaAs substrate 51.

As shown in FIG. 1, the semiconductor laser device 100 comprises the protruding block 110 for placing the RGB three-wavelength semiconductor laser element portion 90 thereon and a stem 107 provided with five lead terminals 101, 102, 103, 104 and 105 electrically insulated from the protruding block 110 while passing through a bottom portion 107a and a lead terminal 106 (broken line) electrically conducting to the protruding block 110 and the bottom portion 107a.

The three green semiconductor laser elements 30 are connected to the lead terminals 101, 102 and 105 respectively through metal wires 71, 72 and 73 wire-bonded to the respective p-side pad electrodes 37 (see FIG. 2). The p-side pad electrodes 37 are examples of the “electrode” in the present invention, and the lead terminals 101, 102 and 105 are examples of the “terminals” in the present invention.

The two blue semiconductor laser elements 50 are connected to one lead terminal 103 in common through metal wires 74 and 75 wire-bonded to the respective p-side pad electrodes 57 (see FIG. 2). The red semiconductor laser element 10 is connected to the lead terminal 104 through a metal wire 76 wire-bonded to the p-side pad electrode 17 (see FIG. 2). The base 91 for placing the semiconductor laser elements (10, 30 and 50) thereon is made of a material such as AlN having conductivity, and electrically connected to the protruding block 110 through the conductive adhesive layer 1. Thus, the semiconductor laser device 100 is formed in a state (cathode-common) where the p-side electrodes (17, 37 and 57) of the respective semiconductor laser elements (10, 30 and 50) are connected to the lead terminals (101, 102, 103, 104 and 105) insulated from each other while the n-side electrodes (18, 38 and 58) are connected to a common cathode terminal (lead terminal 106 (see FIG. 1)).

In each of the red semiconductor laser element 10, the green semiconductor laser elements 30 and the blue semiconductor laser elements 50, light-emitting surfaces and light-reflecting surfaces are formed on both end portions in a cavity direction (direction perpendicular to the plane of FIG. 1). A dielectric multilayer film of low reflectance is formed on the light-emitting surface (surface on the side of the emitting direction of the laser beam of each color) of each semiconductor laser element, while a dielectric multilayer film of high reflectance is formed on the light-reflecting surface (surface opposite to the emitting direction of the laser beam of each color). Multilayer films made of GaN, AlN, BN, Al₂O₃, SiO₂, ZrO₂, Ta₂O₅, Nb₂O₅, La₂O₃, SiN, AlON or MgF₂, or Ti₃O₅ or Nb₂O₃ which is a material having a different mixing ratio of these can be employed as the dielectric multilayer films.

In the red semiconductor laser element 10, the green semiconductor laser elements 30 and the blue semiconductor laser elements 50, optical guiding layers or carrier blocking layers may be formed between the n-type cladding layers and the active layers. Contact layers or the like may be formed on sides of the n-type cladding layers opposite to the active layers. Light guide layers or carrier blocking layers may be formed between the active layers and the p-type cladding layers. Contact layers or the like preferably having smaller band gaps than the p-type cladding layers may be formed on sides of the p-type cladding layers opposite to the active layers. Further, p-side ohmic electrodes may be formed on sides of the p-side pad electrodes closer to the p-type cladding layers.

A manufacturing process for the semiconductor laser device 100 according to the first embodiment is now described with reference to FIGS. 1 and 2.

In the manufacturing process for the semiconductor laser device 100 according to the first embodiment, the n-type contact layer 12, the n-type cladding layer 13, the MQW active layer 14 and the p-type cladding layer 15 are first successively formed on the upper surface of the n-type GaAs substrate 11 by MOCVD, and the ridge 20, the current blocking layer 16 and the p-side pad electrode 17 are thereafter formed, as shown in FIG. 2. Thereafter the lower surface of the n-type GaAs substrate 11 is polished, and the n-side electrode 18 is thereafter formed on the lower surface of the n-type GaAs substrate 11 to prepare a wafer of the red semiconductor laser element 10. Finally, a plurality of chips of the red semiconductor laser element 10 (see FIG. 1) are formed by cleaving the wafer into bars to have a prescribed cavity length while element-dividing the same in the cavity direction.

Each of the green semiconductor laser elements 30 and the blue semiconductor laser elements 50 are formed through manufacturing processes similar to that for the aforementioned red semiconductor laser element 10.

Thereafter the three green semiconductor laser elements 30, the two blue semiconductor laser elements 50 and one red semiconductor laser element 10 are fixed to the base 91 through the conductive adhesive layer 2 while pressing the former against the latter by employing a collet (not shown) made of ceramic, as shown in FIG. 1. At this time, the semiconductor laser elements of the respective colors are so arranged that the laser beams of the respective colors are substantially parallel to each other and the laser elements line up in order of green, blue, green, red, green and blue from one side end portion (B1 side) toward the other side end portion (B2 side) as viewed from the side of the emitting direction of the laser beams. Thus, the RGB three-wavelength semiconductor laser element portion 90 is formed. Thereafter the RGB three-wavelength semiconductor laser element portion 90 is bonded to the protruding block 110 provided on the stem 107 through the conductive adhesive layer 1 while pressing the former against the latter, so that the emitting direction of the laser beams of the respective colors faces the direction of the front surface of the bottom portion 107a of the stem 107. Thus, the base 91 is electrically connected to the lead terminal 106 through the protruding block 110.

Thereafter the p-side pad electrodes 37 of the green semiconductor laser elements 30 and the respective lead terminals 101, 102 and 105 are connected with each other by the respective metal wires 71, 72 and 73, as shown in FIG. 1. The p-side pad electrodes 57 of the blue semiconductor laser elements 50 and the respective lead terminal 103 are connected with each other by the respective metal wires 74 and 75. The p-side pad electrode 17 of the red semiconductor laser elements 10 and the lead terminal 104 are connected with each other by the metal wire 76. Thus, the semiconductor laser device 100 according to the first embodiment is formed.

The structure of a projector 150 which is an example of the “display” in the present invention loaded with the semiconductor laser device 100 according to the first embodiment of the present invention is now described with reference to FIG. 3. In the projector 150, such an example that the individual semiconductor laser elements constituting the semiconductor laser device 100 are substantially simultaneously turned on is described.

The projector 150 comprises the semiconductor laser device 100, an optical system 120 consisting of a plurality of optical components, and a control portion 145 controlling the semiconductor laser device 100 and the optical system 120, as shown in FIG. 3. Thus, the projector 150 is so formed that the laser beams emitted from the semiconductor laser device 100 are modulated by the optical system 120 and thereafter projected on an external screen 144 or the like. The optical system 120 is an example of the “modulation means” in the present invention.

In the optical system 120, the laser beams emitted from the semiconductor laser device 100 are converted to parallel beams having prescribed beam diameters by a dispersion angle control lens 122 consisting of a convex lens and a concave lens, and thereafter introduced into a fly-eye integrator 123. The fly-eye integrator 123 is so formed that two fly-eye lenses consisting of fly-eye lens groups face each other, and provides a lens function to the beams introduced from the dispersion angle control lens 122 so that quantity distributions of the beams incident upon liquid crystal panels 129, 133 and 140 are uniformized. In other words, the beams transmitted through the fly-eye integrator 123 are so adjusted that the same can be incident with spreading of an aspect ratio (16:9, for example) corresponding to the sizes of the liquid crystal panels 129, 133 and 140.

The beams transmitted through the fly-eye integrator 123 are condensed by a condenser lens 124. Among the beams transmitted through the condenser lens 124, only the red beam is reflected by a dichroic mirror 125, while the green beams and the blue beams are transmitted through the dichroic mirror 125.

The red beam is incident upon the liquid crystal panel 129 through an incidence-side polarizing plate 128 after parallelization by a lens 127 through a mirror 126. This liquid crystal panel 129 is driven in response to a driving signal (R image signal) for red thereby modulating the red beam.

Only the green beams in the beams transmitted through the dichroic mirror 125 are reflected by a dichroic mirror 130, while the blue beams are transmitted through the dichroic mirror 130.

The green beams are incident upon the liquid crystal panel 133 through an incidence-side polarizing plate 132 after parallelization by a lens 131. This liquid crystal panel 133 is driven in response to a driving signal (G image signal) for green thereby modulating the green beams.

The blue beams transmitted through the dichroic mirror 130 are incident upon the liquid crystal panel 140 through an incidence-side polarizing plate 139 after passing through a lens 134, a mirror 135, a lens 136 and a mirror 137 and further being parallelized by a lens 138. This liquid crystal panel 140 is driven in response to a driving signal (B image signal) for blue thereby modulating the blue beams.

Thereafter the red beam, the green beams and the blue beams modulated by the liquid crystal panels 129, 133 and 140 are synthesized by a dichroic prism 141, and thereafter introduced into a projection lens 143 through an outgoing-side polarizing plate 142. The projection lens 143 stores a lens group for imaging projected beams on a projected surface (screen 144) and an actuator for adjusting the zoom and the focus of projected images by displacing a part of the lens group in an optical axis direction.

In the projector 150, stationary voltages as an R signal related to driving of the red semiconductor laser element 10, a G signal related to driving of the green semiconductor laser elements 30 and a B signal related to driving of the blue semiconductor laser elements 50 are controlled by the control portion 145 to be supplied to the respective laser elements of the semiconductor laser device 100. Thus, the red semiconductor laser element 10, the green semiconductor laser elements 30 and the blue semiconductor laser elements 50 of the semiconductor laser device 100 are formed to be substantially simultaneously oscillated. The projector 150 is formed to control intensity levels of the beams of the respective ones of the red semiconductor laser element 10, the green semiconductor laser elements 30 and the blue semiconductor laser elements 50 of the semiconductor laser device 100 with the control portion 145, so that hues, brightness etc. of pixels projected on the screen 144 are controlled. Thus, desired images are projected on the screen 144 by the control portion 145. The projector 150 loaded with the semiconductor laser device 100 according to the first embodiment of the present invention is constituted in such a manner.

The structure of a projector 190 which is another example of the “display” in the present invention loaded with the semiconductor laser device 100 according to the first embodiment of the present invention is now described with reference to FIGS. 1, 4 and 5. In the projector 190, such an example that the individual semiconductor laser elements constituting the semiconductor laser device 100 are turned on in a time-series manner is described.

The projector 190 comprises the semiconductor laser device 100, an optical system 160, and a control portion 185 controlling the semiconductor laser device 100 and the optical system 160, as shown in FIG. 4. Thus, the projector 190 is so formed that the laser beams from the semiconductor laser device 100 are modulated by the optical system 160 and thereafter projected on a screen 181 or the like. The optical system 160 is an example of the “modulation means” in the present invention.

In the optical system 160, the laser beams emitted from the semiconductor laser device 100 are converted to respective beams by a lens 162, and thereafter introduced into a light pipe 164.

The light pipe 164 has a mirror-finished inner surface, and the laser beams progress in the light pipe 164 while the same are repetitively reflected on the inner surface of the light pipe 164. At this time, intensity distributions of the laser beams of the respective colors outgoing from the light pipe 164 are uniformized due to multireflection in the light pipe 164. The laser beams outgoing from the light pipe 164 are introduced into a digital micromirror device (DMD) element 166 through a relay optical system 165.

The DMD element 166 consists of a group of small mirrors arranged in the form of a matrix. The DMD element 166 has a function of expressing (modulating) gradations of respective pixels by switching light-reflecting directions on respective pixel positions to a first direction A toward a projection lens 180 and a second direction B deviating from the projection lens 180. Among the laser beams introduced into the respective pixel positions, each beam (ON-light) reflected in the first direction A is introduced into the projection lens 180 and projected on a projected surface (screen 181). On the other hand, each beam (OFF-light) reflected in the second direction B by the DMD element 166 is not introduced into the projection lens 180 but absorbed by a light absorber 167.

The projector 190 is so formed that a pulse power source is controlled by the control portion 185 to be supplied to the semiconductor laser device 100, so that the red semiconductor laser element 10, the green semiconductor laser elements 30 and the blue semiconductor laser elements 50 of the semiconductor laser device 100 are divided in a time-series manner and periodically driven one by one. By the control portion 185, the DMD element 166 of the optical system 160 is formed to modulate the beams in response to the gradations in the respective pixels (R, G and B) in synchronization with driven states of the red semiconductor laser element 10, the green semiconductor laser elements 30 and the blue semiconductor laser elements 50 respectively.

More specifically, the R signal related to driving of the red semiconductor laser element 10 (see FIG. 1), the G signal related to driving of the green semiconductor laser elements 30 (see FIG. 1) and the B signal related to driving of the blue semiconductor laser elements 50 (see FIG. 1) are supplied to the respective laser elements of the semiconductor laser device 100 by the control portion 185 (see FIG. 4) in a state divided in a time-series manner not to overlap each other, as shown in FIG. 5. In synchronization with this B signal, the G signal and the R signal, a B image signal, a G image signal and an R image signal are outputted from the control portion 185 to the DMD element 166 respectively.

Thus, the blue beams of the blue semiconductor laser elements 50 are emitted on the basis of the B signal in the timing chart shown in FIG. 5, while the blue beams are modulated by the DMD element 166 at this timing on the basis of the B image signal. Further, the green beams of the green semiconductor laser elements 30 are emitted on the basis of the G signal output power subsequently to the B signal, while the green beams are modulated by the DMD element 166 at this timing on the basis of the G image signal. In addition, the red beam of the red semiconductor laser element 10 is emitted on the basis of the R signal output power subsequently to the G signal, while the red beam is modulated by the DMD element 166 at this timing on the basis of the R image signal. Thereafter the blue beams of the blue semiconductor laser elements 50 are emitted on the basis of the B signal output power subsequently to the R signal, while the blue beams are modulated by the DMD element 166 at this timing on the basis of the B image signal again. The aforementioned operations are so repeated that images resulting from laser beam application based on the B image signal, the G image signal and the R image signal are projected on the projected surface (screen 181). Thus, the projector 190 loaded with the semiconductor laser device 100 according to the first embodiment of the present invention is constituted.

According to the first embodiment, as hereinabove described, the semiconductor laser device 100 is so formed that the number n1 (three) of the green semiconductor laser elements 30 is larger than the number n2 (two) of the blue semiconductor laser elements 50 and so formed that the number n1 (three) of the green semiconductor laser elements 30 is larger than the number n3 (one) of the red semiconductor laser element 10, whereby each total output power of the green semiconductor laser elements 30 and the blue semiconductor laser elements 50 is easily adjusted and the green semiconductor laser elements 30 and the blue semiconductor laser elements 50 whose respective total output powers are set relatively small can be so formed as to have a desired output power in a case of constituting the semiconductor laser device 100 with reference to the red semiconductor laser element 10 whose output power is large, since the number of the individual semiconductor laser elements constituting each of the green semiconductor laser elements 30 and the blue semiconductor laser elements 50 is rendered larger than that of the red semiconductor laser element 10. Thus, the red semiconductor laser element 10 whose output power is relatively large and the green semiconductor laser elements 30 and the blue semiconductor laser elements 50 of relatively small output powers whose total output powers are properly adjusted can be properly combined with each other, whereby a desired hue can be easily obtained in a case of utilizing the semiconductor laser device 100 as a light source.

According to the first embodiment, the semiconductor laser device 100 is so formed that the number n1 (three) of the green semiconductor laser elements 30 is larger than the number n2 (two) of the blue semiconductor laser elements 50 while the number n1 (three) of the green semiconductor laser elements 30 is larger than the number n3 (one) of the red semiconductor laser element 10, whereby the numbers of the green semiconductor laser elements 30 and the blue semiconductor laser elements 50 can be increased in preference to the number of the red semiconductor laser element 10 in a case of obtaining white light with the aforementioned three types of semiconductor laser elements, since the output power (about 270 mW) of the green semiconductor laser elements 30 and the output power (about 600 mW) of the blue semiconductor laser elements 50 are small as compared with the red semiconductor laser element 10 (about 800 mW) easily obtaining a relatively large output power in particular. Thus, the total output powers of the green semiconductor laser elements 30 and the blue semiconductor laser elements 50 can be easily adjusted, whereby the semiconductor laser device 100 capable of easily obtaining ideal white light can be easily formed.

According to the first embodiment, the numbers (numbers of the laser beam emitting portions) of the green semiconductor laser elements 30 and the blue semiconductor laser elements 50 are so increased that output powers of the individual laser beam emitting portions can be suppressed small, whereby temperature rise of the green semiconductor laser elements 30 and the blue semiconductor laser elements 50 can be suppressed due to the small output powers of the individual laser beam emitting portions. Further, the areas of the laser beam emitting portions are increased in response to the numbers of the laser beam emitting portions in the green semiconductor laser elements 30 and the blue semiconductor laser elements 50, whereby heat generated in the semiconductor laser elements can be released through wider surface areas. Thus, deterioration of the green semiconductor laser elements 30 and the blue semiconductor laser elements 50 is suppressed, whereby the lives of the semiconductor laser elements can be elongated.

According to the first embodiment, the p-side pad electrodes 37 in the three green semiconductor laser elements 30 are connected to the respective different lead terminals 101, 102 and 105 through the metal wires 71, 72 and 73 respectively, so that the green semiconductor laser elements 30 having a larger number of laser beam emitting portions than the red semiconductor laser element 10 and the blue semiconductor laser elements 50 can be individually driven in response to the number of the laser beam emitting portions, whereby the total output power of the green semiconductor laser elements 30 can be easily adjusted in response to the required output powers.

### Second Embodiment

Referring to FIGS. 6 to 8, a case of constituting an RGB three-wavelength semiconductor laser element portion 290 by arranging a monolithic green semiconductor laser element portion 230 in which four green semiconductor laser elements 230a to 230d are integrated, a monolithic blue semiconductor laser element portion 250 in which three blue semiconductor laser elements 250a to 250c are integrated and one red semiconductor laser element 210 on a base 291 is described in this second embodiment, dissimilarly to the aforementioned first embodiment.

In a semiconductor laser device 200 according to the second embodiment of the present invention, the RGB three-wavelength semiconductor laser element portion 290 is fixed onto the upper surface (surface on a C2 side) of a protruding block 206, as shown in FIG. 6.

According to the second embodiment, it is required to adjust output power ratios of the aforementioned three types of semiconductor laser elements in terms of watts in the RGB three-wavelength semiconductor laser element portion 290 to red:green:blue=9.2:8.1:16.7, in order to obtain white light with a red beam of about 635 nm, a green beam of about 530 nm and a blue beam of about 460 nm.

Therefore, the green semiconductor laser elements 230a to 230d each having an output power of about 50 mW are integrated on one substrate 231 so that the green semiconductor laser element portion 230 has a total output power of about 200 mW, as shown in FIG. 7. The blue semiconductor laser elements 250a to 250c each having an output power of about 200 mW are integrated on one substrate 251 so that the blue semiconductor laser element portion 250 has a total output power of about 600 mW, as shown in FIG. 8. The RGB three-wavelength semiconductor laser element portion 290 is constituted by fixing one red semiconductor laser element 210 having an output power of about 350 mW, the green semiconductor laser element portion 230 and the blue semiconductor laser element portion 250 onto the upper surface (surface on a C2 side) of the base 291 at prescribed intervals, as shown in FIG. 6.

In other words, when comparing the numbers of laser beam emitting portions of the respective semiconductor laser elements in the second embodiment, the number (four) of the laser beam emitting portions of the green semiconductor laser element portion 230 whose total output power is relatively small is rendered larger than the number (one) of the red semiconductor laser element 210 whose output power is relatively large. Further, the laser beam emitting portions (four) of the green semiconductor laser element portion 230 are provided in a larger number than the number (three) of the laser beam emitting portions of the blue semiconductor laser element portion 250 whose total output power is relatively large.

According to the second embodiment, the green semiconductor laser element portion 230 is arranged substantially at the center of the semiconductor laser device 200 on the base 291 in the width direction (direction B) so that an emitting direction (direction A1) of laser beams is orthogonal to the direction B, while the red semiconductor laser element 210 is arranged to be adjacent to the green semiconductor laser element portion 230 on one side end portion side (side of a direction B1) on the base 291 so that an emitting direction of a laser beam is substantially parallel to the emitting direction (direction A1) of the laser beams from the green semiconductor laser element portion 230. The blue semiconductor laser element portion 250 is arranged on a side (direction B2) opposite to the red semiconductor laser element 210 so as to be adjacent to the green semiconductor laser element portion 230 while an emitting direction of laser beams is substantially parallel to the emitting direction (direction A1) of the laser beams from the green semiconductor laser element portion 230. A cavity length (about 2 mm) of the red semiconductor laser element 210 is larger than cavity lengths (both about 1 mm) of the green semiconductor laser element portion 230 and the blue semiconductor laser element portion 250. The three types of semiconductor laser elements are so arranged that light-emitting surfaces agree with a substantially identical plane.

The green semiconductor laser elements 230a to 230d are integrally formed on the substrate 231 through recess portions 5, as shown in FIG. 7. One p-side pad electrode 237 is formed over the green semiconductor laser elements 230a to 230d on surfaces of the green semiconductor laser elements 230a to 230d on the side (C2 side) of p-type cladding layers 35. An n-side electrode 238 is formed on the lower surface (C1 side) of the substrate 231.

The blue semiconductor laser elements 250a to 250c are integrally formed on the substrate 251 through recess portions 6 reaching an n-type GaN layer 52 from the upper surface (surface on the C2 side) of the blue semiconductor laser element portion 250, as shown in FIG. 8. A current blocking layer 56 is formed to cover the side surfaces and the bottom surfaces of the recess portions 6. One p-side pad electrode 257 is formed over the blue semiconductor laser elements 250a to 250c on surfaces of the blue semiconductor laser elements 250a to 250c on the side (C2 side) of p-type cladding layers 55. An n-side electrode 258 is formed on the lower surface (C1 side) of the substrate 251. The remaining structure of the blue semiconductor laser element portion 250 is similar to that of the blue semiconductor laser elements 50 in the aforementioned first embodiment.

As shown in FIG. 6, the semiconductor laser device 200 comprises a protruding block 206 for placing the RGB three-wavelength semiconductor laser element portion 290 thereon and a stem 205 provided with three lead terminals 201, 202 and 203 electrically insulated from the protruding block 206 while passing through a bottom portion 205a and the other lead terminal (not shown) electrically conducting to the protruding block 206 and the bottom portion 205a.

The red semiconductor laser element 210 is connected to the lead terminal 201 through a metal wire 271 wire-bonded to a p-side pad electrode 17. The green semiconductor laser element portion 230 is connected to the lead terminal 202 through a metal wire 272 wire-bonded to the p-side pad electrode 237. The blue semiconductor laser element 250 is connected to the lead terminal 203 through a metal wire 273 wire-bonded to the p-side pad electrode 257. The red semiconductor laser element 210, the green semiconductor laser element portion 230 and the blue semiconductor laser element portion 250 are electrically connected onto the upper surface (surface on the C2 side) of the base 291 through a conductive adhesive layer (not shown) of AuSn solder or the like, while the base 291 is electrically connected to the protruding block 206 through a conductive adhesive layer (not shown) of AuSn solder or the like. As shown in FIG. 6, the semiconductor laser device 200 is so formed that laser beams of respective colors are emitted from a cavity facet of the RGB three-wavelength semiconductor laser element portion 290 on an A1 side.

A manufacturing process for the semiconductor laser device 200 according to the second embodiment is similar to that in the aforementioned first embodiment.

According to the second embodiment, as hereinabove described, the four green semiconductor laser elements 230a to 230d are formed on the common substrate 231 to form the monolithic green semiconductor laser element portion 230 while the three blue semiconductor laser elements 250a to 250c are formed on the common substrate 251 to form the monolithic blue semiconductor laser element portion 250, so that the green semiconductor laser element portion 230 and the blue semiconductor laser element portion 250 are integrated and formed on the substrates common thereto in response to the lasing wavelengths, whereby the widths of the green semiconductor laser element portion 230 and the blue semiconductor laser element portion 250 in the direction B can be reduced due to the integration. Thus, the semiconductor laser elements can be easily arranged in a package (on the base 291) in states of integrated laser elements also in a case where a large number of laser beam emitting portions (four in the green semiconductor laser element portion 230, for example) are required. The remaining effects of the second embodiment are similar to those of the aforementioned first embodiment.

### Third Embodiment

A third embodiment is described with reference to FIG. 6 and FIGS. 8 to 12. In this third embodiment, a case of constituting an RGB three-wavelength semiconductor laser element portion 390 by arranging a monolithic two-wavelength semiconductor laser element portion 370 in which a green semiconductor laser element portion 330 consisting of three green semiconductor laser elements 330a to 330c and a blue semiconductor laser element portion 350 consisting of two blue semiconductor laser element 350a and 350b are integrated and one red semiconductor laser element 10 on a base 391 is described, dissimilarly to the aforementioned second embodiment.

In a semiconductor laser device 300 according to the third embodiment of the present invention, the RGB three-wavelength semiconductor laser element portion 390 is fixed onto the upper surface of a base 206, as shown in FIG. 9.

According to the third embodiment, it is required to adjust output power ratios of the aforementioned three types of semiconductor laser elements in terms of watts in the RGB three-wavelength semiconductor laser element portion 390 to red:green:blue=24.5:9.9:7.2, in order to obtain white light with a red beam of about 655 nm, a green beam of about 520 nm and a blue beam of about 480 nm.

Therefore, the green semiconductor laser element portion 330 constituting the two-wavelength semiconductor laser element portion 370 and having a total output power of about 300 mW, in a state where the green semiconductor laser elements 330a to 330c each having an output power of about 100 mW are integrated, and the blue semiconductor laser element portion 350 having a total output power of about 240 mW, in a state where the blue semiconductor laser elements 350a and 350b each having an output power of about 120 mW are integrated, are formed on a common n-type GaN substrate 331 having a major surface consisting of a (11-22) plane, as shown in FIG. 9. One red semiconductor laser element 10 having an output power of about 800 mW and the two-wavelength semiconductor laser element portion 370 are fixed onto the upper surface of the base 391 through a conductive adhesive layer (not shown) of AuSn solder or the like at a prescribed interval, whereby the RGB three-wavelength semiconductor laser element portion 390 is formed. In the two-wavelength semiconductor laser element portion 370, the green semiconductor laser element portion 330 and the blue semiconductor laser element portion 350 are integrated and formed on the common n-type GaN substrate 331 having the major surface of the (11-22) plane. The n-type GaN substrate 331 is an example of the “substrate” in the present invention.

According to the third embodiment, the (11-22) plane of the n-type GaN substrate 331 is constituted of a semipolar plane consisting of a plane inclined from a c-plane ((0001) plane) toward a [1]-20] direction by about 58°, as shown in FIG. 10. A plane inclined from the c-plane by at least about 10° and not more than about 70° is preferably employed as the semipolar plane. Thus, it is possible to substantially agree extensional directions of waveguides in which optical gains are maximized with each other in the green semiconductor laser element portion 330 and the blue semiconductor laser element portion 350. The (11-22) plane has a small piezoelectric field as compared with other semipolar planes, whereby it is possible to suppress reduction of luminous efficiency of the blue semiconductor laser element portion 350 and the green semiconductor laser element portion 330. Therefore, the aforementioned (11-22) plane is more preferably employed as the major surface of the n-type GaN substrate 331.

In the blue semiconductor laser element portion 350, an n-type GaN layer 52, n-type cladding layers 53a made of Si-doped n-type Al_{0.07}Ga_{0.93}N each having a thickness of about 2 μm, n-type carrier blocking layers 53b made of Si-doped n-type Al_{0.16}Ga_{0.84}N each having a thickness of about 5 nm and n-type optical guiding layers 53c made of Si-doped n-type In_{0.02}Ga_{0.98}N each having a thickness of about 100 nm are formed on a region of the upper surface of the n-type GaN substrate 331 on the side of a [−1100] direction (direction B1).

Active layers 54 in the blue semiconductor laser element portion 350 have major surfaces consisting of the same (11-22) planes as the n-type GaN substrate 331. More specifically, each active layer 54 is formed by alternately stacking four barrier layers 54a made of undoped In_{0.02}Ga_{0.98}N each having a thickness of about 20 nm and three well layers 54b made of undoped In_{0.20}Ga_{0.80}N each having a thickness of about 3 nm on the upper surface of each n-type optical guiding layer 53c, as shown in FIG. 11. The in-plane lattice constant of the well layers 54b is larger than the lattice constant in the plane of the n-type GaN substrate 331, and hence a compressive strain is applied in the in-plane direction. In other words, the well layers 54b of the active layers 54 of the blue semiconductor laser element portion 350 have an In composition of about 20%. As compared with a case of applying the c-planes ((0001) planes) which are the polar planes and other semipolar planes to the major surfaces of the active layers 54, it is possible to reduce piezoelectric fields in the active layers 54 by setting the (11-22) planes to the major surfaces of the active layers 54.

The semiconductor laser device 300 is so formed that a polarization direction in which oscillator strength is maximized in the major surface of the blue semiconductor laser element portion 350 is a [1-100] direction which is a direction perpendicular to an m-plane ((1-100) plane) which is a non-polar plane.

In the blue semiconductor laser element portion 350, p-type optical guiding layers 55a made of Mg-doped In_{0.02}Ga_{0.98}N each having a thickness of about 100 nm, p-type carrier blocking layers 55b made of Mg-doped p-type Al_{0.16}Ga_{0.84}N each having a thickness of about 20 nm, p-type cladding layers 55c made of Mg-doped p-type Al_{0.07}Ga_{0.93}N each having a thickness of about 700 nm and p-type contact layers 55d made of Mg-doped p-type In_{0.02}Ga_{0.98}N each having a thickness of about 10 nm are formed on the upper surfaces of the active layers 54, as shown in FIG. 10.

Striped ridges 360 formed on substantially central portions of the blue semiconductor laser element portion 350 in a direction B (direction B1 and direction B2) by the p-type cladding layers 55c and the p-type contact layers 55d are formed to extend along the extensional direction ([−1-123] direction) of the waveguides, which is a direction obtained by projecting a [0001] direction onto the (11-22) plane, as shown in FIG. 10.

A current blocking layer 376 consisting of an insulating film is formed to cover the upper surfaces of planar portions of the p-type cladding layers 55c, the side surfaces of the ridges 350 and the side surfaces of n-type semiconductor layers (53), the active layers 54, the p-type optical guiding layers 55a, the p-type carrier blocking layers 55b and the p-type cladding layers 55c so that the upper surfaces of the ridges 360 are exposed. This current blocking layer 376 is made of SiO₂, and has a thickness of about 250 nm. The current blocking layer 376 is formed to cover a prescribed region (region exposed from the blue semiconductor laser element portion 350 and the green semiconductor laser element portion 330) of the upper surface of the n-type GaN substrate 331, the upper surfaces of planar portions of p-type cladding layers 35c, described later, of the green semiconductor laser element portion 350, the side surfaces of ridges 340 described later, and the side surfaces of n-type semiconductor layers (33), active layers 34 and a part of p-type semiconductor layers (35), so that the upper surfaces of the ridges 340 are exposed. Further, the current blocking layer 376 is formed to cover the side surfaces and the bottom surfaces of recess portions 7. P-side ohmic electrodes 56 in which Pt layers each having a thickness of about 5 nm, Pd layers each having a thickness of about 100 nm and Au layers each having a thickness of about 150 nm are stacked successively from the side closer to the p-type contact layers 55d are formed on the upper surfaces of the p-type contact layers 55d.

The blue semiconductor laser elements 350a and 350b arranged in line in the direction (direction B) where the laser elements are arrayed through a recess portion 6 in the blue semiconductor element portion 350 are formed on the other side (B1 side) of the upper surface of the n-type GaN substrate 331 from the green semiconductor laser element portion 330 through a recess portion 8. In the green semiconductor laser elements 330a to 330c arranged in line in the direction (direction B) where the laser elements are arrayed through the recess portions 7 in the green semiconductor laser element portion 330, an n-type GaN layer 32 having a thickness of about 1 μm, n-type cladding layers 33a made of Si-doped n-type Al_{0.10}Ga_{0.90}N each having a thickness of about 2 μm, n-type carrier blocking layers 33b made of Si-doped n-type Al_{0.20}Ga_{0.80}N each having a thickness of about 5 nm and n-type optical guiding layers 33c made of Si-doped n-type In_{0.05}Ga_{0.95}N each having a thickness of about 100 nm are formed on regions on the side of the [1-100] direction (direction B2) of the upper surface of the n-type GaN substrate 331 which is the same substrate as the blue semiconductor laser element portion 350, as shown in FIG. 10.

The active layers 34 in the green semiconductor laser element portion 330 have major surfaces consisting of the same (11-22) planes as the n-type GaN substrate 331. More specifically, each active layer 34 has an SQW structure in which two barrier layers 34a made of undoped In_{0.02}Ga_{0.98}N each having a thickness of about 20 nm and one well layer 34b made of undoped In_{0.33}Ga_{0.67}N having a thickness t6 of about 3.5 nm are alternately stacked on the upper surface of each n-type optical guiding layer 33c, as shown in FIG. 12. The in-plane lattice constant of the well layer 34b is larger than the in-plane lattice constant of the n-type GaN substrate 331 (see FIG. 10), and hence a compressive strain is applied in the in-plane direction. The compressive strain of each well layer 34b of the green semiconductor laser element portion 330 is larger than the compressive strain of each well layer 54b of the blue semiconductor laser element portion 350. The thickness t6 of the well layer 34b is preferably less than about 6 nm. The thickness t6 of the well layer 34b of the active layer 34 is so sufficiently small that the well layer 34b can maintain a layered structure since the active layer 34 has the SQW structure, as compared with a case where the active layer 34 has an MQW structure. The well layer 34b is an example of the “second well layer” in the present invention. In other words, the well layer 34b of each active layer 34 of the green semiconductor laser element portion 330 has an In composition of about 33% larger than the In composition (about 20%) in each well layer 54b of each active layer 54 of the blue semiconductor laser element portion 350. Thus, the semiconductor laser device 300 is so formed that the extensional direction of waveguides (ridges 340) in which gains of the green semiconductor laser elements 330a to 330c are maximized and the extensional direction of waveguides (ridges 360) in which a gain of the blue semiconductor laser element portion 350 is maximized become the same direction ([−1-123] direction).

The extensional direction of the waveguides (ridges 340) in which the gains of the aforementioned green semiconductor laser elements 330a to 330c are maximized and the extensional direction of the waveguides (ridges 360) in which the gain of the blue semiconductor laser element portion 350 is maximized become the same direction ([−1-123] direction) on the basis of the fact that such a phenomenon has been found that, in a case where an In composition is at least about 30%, a principal polarization direction in a (11-22) plane rotates by 90° (rotates from the [1-100] direction to the [−1-123] direction) if the thickness of a well layer made of InGaN having a major surface of a (11-22) plane is less than about 3 nm. Thus, the thickness t6 of the well layer 34b is more preferably at least about 3 nm in a case where the well layer 34b has an In composition of at least about 30%. Further, it is possible to form the semiconductor laser device 300 by constituting the well layer 34b made of InGan having the In composition of about 33% and having the major surface of the (11-22) plane to have the thickness t6 of about 3.5 nm (at least about 3 nm) so that the 90° change of the extensional direction of the waveguides (ridges 340) in which the optical gains of the green semiconductor laser elements 330a to 330c are maximized does not occur with respect to the extensional direction of the waveguides (ridges 360) in which the optical gain of the blue semiconductor laser element portion 350 is maximized. The in-plane lattice constant of the well layer 34b is larger than the lattice constant in the plane of the n-type GaN substrate 331 (see FIG. 10), and hence the compressive strain is applied in the in-plane direction. The compressive strain of each well layer 34b of the green semiconductor laser element portion 330 is larger than the compressive strain of each well layer 54b of the blue semiconductor laser element portion 350. As compared with a case of setting the c-plane ((0001) plane) which is the polar plane or another semipolar plane to the major surface of each active layer 34, it is possible to reduce the piezoelectric field in the active layer 34 by setting the (11-22) plane to the major surface of the active layer 34.

The semiconductor laser device 300 is so formed that the thickness t6 (about 3.5 nm) of the well layer 34b of each of the active layers 34 of the green semiconductor laser elements 330a to 330c shown in FIG. 12 is larger (t6 a t5) than the thickness t5 (about 3 nm) of each layer in the well layers 54b of the active layers 54 of the blue semiconductor laser element portion 350 shown in FIG. 11.

In the green semiconductor laser elements 330a to 330c, p-type optical guiding layers 35a made of Mg-doped p-type In_{0.05}Ga_{0.95}N each having a thickness of about 100 nm, p-type carrier blocking layers 35b made of Mg-doped p-type Al_{0.20}Ga_{0.80}N each having a thickness of about 20 nm, the p-type cladding layers 35c made of Mg-doped p-type Al_{0.10}Ga_{0.90}N each having a thickness of about 700 nm and p-type contact layers 35d made of Mg-doped p-type In_{0.02}Ga_{0.98}N each having a thickness of 10 nm are formed on the upper surfaces of the active layers 34, as shown in FIG. 10.

The striped ridge 340 is formed on substantially each of central portions of the green semiconductor laser elements 330a to 330c in the direction B (direction B1 and direction B2) are formed to extend along the extensional direction ([−1-123] direction) of the waveguides which is the direction obtained by projecting the [0001] direction onto the (11-22) plane.

The semiconductor laser device 300 is so formed that the Al compositions (about 10%) in the n-type cladding layers 33a and the p-type cladding layers 35c of the green semiconductor laser elements 330a to 330c are large as compared with the Al compositions (about 7) in the n-type cladding layers 53a and the p-type cladding layers 55c of the blue semiconductor laser element portion 350. Further, the semiconductor laser device 300 is so formed that the Al compositions (about 20%) in the n-type carrier blocking layers 33b and the p-type carrier blocking layers 35b of the green semiconductor laser elements 330a to 330c are large as compared with the Al compositions (about 16%) in the n-type carrier blocking layers 53b and the p-type carrier blocking layers 55b of the blue semiconductor laser element portion 350. In addition, the semiconductor laser device 300 is so formed that the In compositions (about 5) in the n-type optical guiding layers 33c and the p-type optical guiding layers 35a of the green semiconductor laser elements 330a to 330c are large as compared with the In compositions (about 2) in the n-type optical guiding layers 53c and the p-type optical guiding layers 55a of the blue semiconductor laser element portion 350. Due to the aforementioned structure, it is possible to confine green beams having small refractive indices between the cladding layers and the carrier blocking layers and the optical guiding layers to a degree substantially identical to blue beams, whereby it is possible to ensure light confinement in the green semiconductor laser elements 330a to 330c to a degree substantially identical to the blue semiconductor laser element portion 350.

The Al compositions in the n-type cladding layers 33a, the n-type carrier blocking layers 33b, the p-type carrier blocking layers 35b and the p-type cladding layers 35c of the green semiconductor laser elements 330a to 330c are preferably large as compared with the Al compositions in the n-type cladding layers 53a, the n-type carrier blocking layers 53b, the p-type carrier blocking layers 55b and the p-type cladding layers 55c of the blue semiconductor laser elements 350a and 350b respectively. On the other hand, it is possible to reduce formation of cracking or warpage resulting from different lattice constants between crystal lattices of AlGaN and the n-type GaN substrate 331 by reducing the Al compositions in the blue semiconductor laser elements 350a and 350b and the green semiconductor laser elements 330a to 330c, while the light confinement function is reduced.

The In compositions in the n-type optical guiding layers 33c and the p-type optical guiding layers 35a of the green semiconductor laser elements 330a to 330c are preferably large as compared with the In compositions in the n-type optical guiding layers 53c and the p-type optical guiding layers 55a of the blue semiconductor laser elements 350a and 350b.

P-side ohmic electrodes 36 made of a material similar to that for the p-side ohmic electrodes 56 of the blue semiconductor laser element portion 350 are formed on the upper surfaces of the p-type contact layers 35d.

In the two-wavelength semiconductor laser element portion 370 on the n-type GaN substrate 331, the three green semiconductor laser elements 330a to 330c are formed through the recess portions 7 reaching the n-type GaN layer 32 from the upper surface (surface on a O₂ side) of the two-wavelength semiconductor laser element portion 370 while the two blue semiconductor laser elements 350a and 350b are formed through the recess portion 6 reaching the n-type GaN layer 52 from the upper surface of the two-wavelength semiconductor laser element portion 370, to be adjacent to the side of the green semiconductor laser element 330a through the recess portion 8 reaching the n-type GaN substrate 331 from the upper surface of the two-wavelength semiconductor laser element portion 370, as shown in FIG. 10.

As shown in FIG. 10, the current blocking layer 376 made of SiO₂ is formed to cover both side surfaces of the ridges 340 of the green semiconductor laser elements 330a to 330c, the planar portions of the p-type cladding layers 35c and the inner side surfaces and the bottom surfaces of the recess portions 7. This current blocking layer 376 is formed to cover the inner side surfaces and the bottom surface of the recess portion 8, both side surfaces of the ridges 360 of the blue semiconductor laser element 350 and the planar portions of the p-type cladding layers 55c.

As shown in FIG. 10, a p-side pad electrode 337 in which a Ti layer having a thickness of about 100 nm, a Pd layer having a thickness of about 100 nm and an Au layer having a thickness of about 3 μm are stacked successively from the side closer to the p-side ohmic electrodes 36 is formed on the current blocking layer 376 of the green semiconductor laser elements 330a to 330c to be electrically connected with the p-side ohmic electrodes 36, while a p-side pad electrode 357 having a structure similar to that of the p-side pad electrode 337 and electrically connected with the p-side ohmic electrodes 56 is formed on the current blocking layer 376 of the blue semiconductor laser elements 350a and 350b. An n-side electrode 378 consisting of an Al layer having a thickness of about 10 nm, a Pt layer having a thickness of about 20 nm and an Au layer having a thickness of about 300 nm successively from the side closer to the n-type GaN substrate 331 is formed on the lower surface (surface on a C1 side) of the n-type GaN substrate 331.

As shown in FIG. 9, a cavity facet perpendicular to the extensional direction ([−1-123] direction) of the waveguides is formed on each of the blue semiconductor laser elements 350a and 350b and the green semiconductor laser elements 330a to 330c. In other words, the blue semiconductor laser element portion 350 and the green semiconductor laser element portion 330 are formed to have cavity facets consisting of the same surface orientation. The remaining structures of the green semiconductor laser elements 330a to 330c and the blue semiconductor laser elements 350a and 350b constituting the two-wavelength semiconductor laser element portion 370 are similar to those of the green semiconductor laser element portion 230 and the blue semiconductor laser element portion 250 in the aforementioned second embodiment.

As shown in FIG. 9, the red semiconductor laser element 10 is arranged on the B1 direction side of the base 391, while the two-wavelength semiconductor laser element portion 370 is arranged on a B2 direction side. A cavity length (about 2 mm) of the red semiconductor laser element 10 is longer than a cavity length (about 1 mm) of the two-wavelength semiconductor laser element portion 370.

The red semiconductor laser element 10 is connected to a lead terminal 201 through a metal wire 371 wire-bonded to a p-side pad electrode 17. The green semiconductor laser element 330 of the two-wavelength semiconductor laser element portion 370 is connected to a lead terminal 203 through a metal wire 372 wire-bonded to the p-side pad electrode 337. The blue semiconductor laser element portion 350 is connected to a lead terminal 202 through a metal wire 373 wire-bonded to the p-side pad electrode 357. The remaining structure of the semiconductor laser device 300 according to the third embodiment is similar to that of the aforementioned second embodiment.

A manufacturing process for the semiconductor laser device 300 according to the third embodiment is now described with reference to FIGS. 9 and 10.

In the manufacturing process for the semiconductor laser device 300 according to the third embodiment, the n-type GaN layer 52, the n-type cladding layers 53a, the n-type carrier blocking layers 53b, the n-type optical guiding layers 53c, the active layers 54, the p-type optical guiding layers 55a, the p-type carrier blocking layers 55b and the p-type cladding layers 55c for constituting the blue semiconductor laser element portion 350 are successively formed on the upper surface of the n-type GaN substrate 331 having the major surface consisting of the (11-22) plane by MOCVD first, as shown in FIG. 10. Thereafter the semiconductor layers from the n-type GaN layer 52 to the p-type cladding layers 55c are partly etched to partly expose the n-type GaN substrate 331, and the n-type GaN layer 32, the n-type cladding layers 33a, the n-type carrier blocking layers 33b, the n-type optical guiding layers 33c, the active layers 34, the p-type optical guiding layers 35a, the p-type carrier blocking layers 35b and the p-type cladding layers 35c for constituting the green semiconductor laser element portion 330 are successively formed on part of the exposed portion while leaving a region for forming the recess portion 8. Thereafter the recess portion 6 whose bottom surface reaches the n-type GaN layer 52 is formed in order to separate the semiconductor layers into the blue semiconductor laser elements 350a and 350b. Similarly, the recess portions 7 whose bottom surfaces reach the n-type GaN layer 32 are formed in order to separate the semiconductor layers into the green semiconductor laser elements 330a, 330b and 330c.

Then, two ridges 360 and three ridges 340 extending along the extensional direction ([−1-123] direction) of the waveguides are formed, and the p-type contact layers 35d and 55d and the p-side ohmic electrodes 36 and 56 are thereafter formed on the respective ridges. Thereafter the current blocking layer 376 is formed to cover the surfaces of the p-type cladding layers 35c (55c) and the side surfaces and the bottom surfaces of both the recess portion 6, the recess portions 7 and the recess portion 8. Further, the p-side pad electrodes 337 and 357 are formed on the respective laser elements to cover a prescribed region of the current blocking layer 376 and the p-side ohmic electrodes 36 and 56. Thus, the p-side pad electrode 337 formed on the side surfaces and the bottom surfaces of the recess portions 7 and employed in common to the green semiconductor laser elements 330a to 330c is formed. Further, the p-side pad electrode 357 formed on the side surfaces and the bottom surface of the recess portion 6 and employed in common to the blue semiconductor laser elements 350a and 350b is formed.

The green semiconductor laser element portion 330 is formed on the surface of the same n-type GaN substrate 331 as the n-type GaN substrate 331 provided with the blue semiconductor laser element portion 350 after forming the blue semiconductor laser element portion 350, so that the active layers 34 of the green semiconductor laser element portions 330 easily deteriorated by heat due to large In compositions are not influenced by heat for forming the blue semiconductor laser element portion 350. Thus, the blue semiconductor laser element portion 350 and the green semiconductor laser element portion 330 separated from each other by the recess portion 8 whose bottom portion reaches the n-type GaN substrate 331 at a prescribed interval in the direction B are prepared.

Thereafter the lower surface of the n-type GaN substrate 331 is polished until the thickness thereof reaches about 100 μm, and a wafer of the two-wavelength semiconductor laser element portion 370 is thereafter prepared by forming the n-side electrode 378 on the lower surface of the n-type GaN substrate 331. Thereafter the cavity facets perpendicular to the extensional direction ([−1-123] direction) of the waveguides are formed on prescribed positions by etching. The cavity facets may alternatively be formed by cleaving the wafer on prescribed positions. Further, a plurality of two-wavelength semiconductor laser element portions 370 (see FIG. 9) are formed by performing element division and bringing the wafer into chips along the cavity direction ([−1-123] direction).

Thereafter the RGB three-wavelength semiconductor laser element portion 390 is formed by fixing the red semiconductor laser element 10 and the two-wavelength semiconductor laser element portion 370 to the base 391 through the conductive adhesive layer of AuSn solder or the like while pressing the former against the latter, as shown in FIG. 9. The remaining manufacturing process in the third embodiment is similar to that in the aforementioned second embodiment.

According to the third embodiment, as hereinabove described, the green semiconductor laser element portion 330 and the blue semiconductor laser element portion 350 are so formed on the common n-type GaN substrate 331 that the green semiconductor laser element portion 330 and the blue semiconductor laser element portion 350 are formed as the two-wavelength semiconductor laser element portion 370 integrated on the common n-type GaN substrate 331, whereby the width of the two-wavelength semiconductor laser element portion 370 in the direction B can be reduced due to the integration as compared with a case where the green semiconductor laser element portion 330 and the blue semiconductor laser element portion 350 are formed on different substrates and thereafter arranged in a package (on the base 391) at a prescribed interval. Thus, the two-wavelength semiconductor laser element portion 370 can be easily arranged in the package (on the base 391) also in a case where a large number of laser beam emitting portions (three in the green semiconductor laser element portion 330, for example) are required.

According to the third embodiment, the well layers 34b of the active layers 34 having the major surfaces consisting of the (11-22) planes in the green semiconductor laser elements 330a to 330c constituting the green semiconductor laser element portion 330 are formed to have the thickness t6 of about 3.5 nm, whereby the extensional direction ([−1-123] direction) of the waveguides in which the optical gains of the blue semiconductor laser elements 350a and 350b are maximized and the extensional direction ([−1-123] direction) of the waveguides in which the optical gain of the green semiconductor laser element portion 330 is maximized can be agreed with each other.

According to the third embodiment, the In composition in the well layers 34b is set to at least about 30% while the thickness of the well layers 34b is set to at least about 3 nm, whereby the extensional direction ([−1-123] direction) of the waveguides in which the optical gain of the blue semiconductor laser element 350 is maximized and the extensional direction ([−1-123] direction) of the waveguides in which the optical gain of the green semiconductor laser element portion 330 is maximized can be agreed with each other.

According to the third embodiment, the semiconductor laser device 300 is so formed that the well layers 34b of the active layers 34 of the green semiconductor laser element portion 330 are made of InGaN having a larger In composition than the In composition in the well layers 54b of the active layers 54 of the blue semiconductor laser element portion 350, whereby the extensional direction ([−1-123] direction) of the waveguides in which the optical gain of the blue semiconductor laser element portion 350 is maximized and the extensional direction ([−1-123] direction) of the waveguides in which the optical gain of the green semiconductor laser element portion 330 is maximized can be agreed with each other.

According to the third embodiment, the thickness t6 (about 3.5 nm: see FIG. 12) of the well layers 34b is rendered larger (t6>t5) than the thickness t5 (about 3 nm: see FIG. 11) of the well layers 54b, whereby formation of misfit dislocations resulting from different lattice constants of the crystal lattices of the well layers 54b having a large In composition and the crystal lattices of underlayers (barrier layers 54a), having a small In composition, on which the well layers 54b are grown can be suppressed in the active layers 54 of the blue semiconductor laser element portion 350.

According to the third embodiment, the (11-22) plane which is the plane inclined by about 58° is so employed as the semipolar plane that the extensional directions of the waveguides in which the optical gains are maximized in the green semiconductor laser element portion 330 and the blue semiconductor laser element portion 350 can be more reliably substantially agreed with each other.

According to the third embodiment, each of the blue semiconductor laser element portion 350 and the green semiconductor laser element portion 330 is so provided with the waveguide extending in the direction ([−1-123] direction) obtained by projecting the [0001] direction onto the (11-22) plane that the each of optical gains of the blue semiconductor laser element 350 and the green semiconductor laser element portion 330 can be maximized while blue beams of the blue semiconductor laser element portion 350 and green beams of the green semiconductor laser element portion 330 can be emitted from cavity facets on a common plane.

According to the third embodiment, the active layers 54 of the blue semiconductor laser element portion 350 are made of InGaN having the major surfaces of the (11-22) planes which are the same major surfaces as the n-type GaN substrate 331 while the active layers 34 of the green semiconductor laser element portion 330 are made of InGaN having the major surfaces of the (11-22) planes which are the same major surfaces as the n-type GaN substrate 331, whereby the green semiconductor laser element portion 330 including the active layers 34 made of InGaN having the major surfaces of the (11-22) planes and the blue semiconductor laser element portion 350 including the active layers 54 made of InGaN having the major surfaces of the (11-22) planes can be both easily formed by simply growing semiconductor layers on the surface of the n-type GaN substrate 331 made of GaN having the same major surface of the (11-22) as the active layers 34 of the green semiconductor laser element portion 330 and the active layers 54 of the blue semiconductor laser element portion 350.

According to the third embodiment, each of the blue semiconductor laser element portion 350 and the green semiconductor laser element portion 330 is provided with the waveguide extending in the direction ([−1-123] direction) obtained by projecting the [0001] direction onto the (11-22) plane, whereby each of the optical gains of the blue semiconductor laser element portion 350 and the green semiconductor laser element portion 330 can be maximized while the blue beams of the blue semiconductor laser element portion 350 and the green beams of the green semiconductor laser element portion 330 can be emitted from the cavity facets on a common plane.

According to the third embodiment, the n-type optical guiding layers 33c and the p-type optical guiding layers 35a can more confine beams in the active layers (active layers 34 and 54) than the n-type optical guiding layers 53c and the p-type optical guiding layers 55a by forming the semiconductor laser device 300 so that the In composition (about 5%) in the n-type optical guiding layers 33c and the p-type optical guiding layers 35a of the green semiconductor laser element portion 330, whereby the green beams of the green semiconductor laser element portion 330 can be more confined in the active layers 34. Thus, light confinement can be ensured in the green semiconductor laser element portion 330 inferior in luminous efficiency as compared with the blue semiconductor laser element portion 350 to a degree substantially identical to the blue semiconductor laser element portion 350.

According to the third embodiment, the n-type carrier blocking layers 33b and the p-type carrier blocking layers 35b can more confine beams in the active layers (active layers 34 and 54) than the n-type carrier blocking layers 53b and the p-type carrier blocking layers 55b by forming the semiconductor laser device 300 so that the Al composition (about 20%) in the n-type carrier blocking layers 33b and the p-type carrier blocking layers 35b of the green semiconductor laser element portion 330, whereby the green beams of the green semiconductor laser element portion 330 can be more confined in the active layers 34. Thus, light confinement can be ensured in the green semiconductor laser element portion 330 inferior in luminous efficiency as compared with the blue semiconductor laser element portion 350 to a degree substantially identical to the blue semiconductor laser element portion 350.

According to the third embodiment, n-type cladding layers 33a and the p-type cladding layers 35c can more confine beams in the active layers (active layers 34 and 54) than the n-type cladding layers 55a and the p-type cladding layers 55c by forming the semiconductor laser device 300 so that the Al composition (about 10%) in the n-type cladding layers 33a and the p-type cladding layers 35c of the green semiconductor laser element portion 330, whereby the green beams of the green semiconductor laser element portion 330 can be more confined in the active layers 34. Thus, light confinement can be ensured in the green semiconductor laser element portion 330 inferior in luminous efficiency as compared with the blue semiconductor laser element portion 350 to a degree substantially identical to the blue semiconductor laser element portion 350. The remaining effects of the third embodiment are similar to those of the aforementioned first embodiment.

(Modification of Third Embodiment)

A modification of the third embodiment is described with reference to FIGS. 10, 12 and 13. In this modification of the third embodiment, a case where the thickness of active layers 54 of blue semiconductor laser elements 350a and 350b is larger than the thickness of active layers 34 of green semiconductor laser elements 330a to 330c is described, dissimilarly to the aforementioned third embodiment.

In other words, each of the active layers 54 of the blue semiconductor laser elements 350a and 350b according to the modification of the third embodiment has an SQW structure made of InGaN having a major surface of a (11-22) plane, as shown in FIG. 13. In other words, the active layer 54 is constituted of two barrier layers 54c, made of undoped In_{0.02}Ga_{0.98}N each having a thickness of about 20 nm, formed on the upper surface of an n-type optical guiding layer 53c and one well layer 54d, made of undoped In_{0.20}Ga_{0.80}N having a thickness t7 of about 8 nm, arranged between the two barrier layers 54c. The in-plane lattice constant of the well layer 54d is larger than the in-plane lattice constant of an n-type GaN substrate 331 (see FIG. 10), and hence a compressive strain is applied in the in-plane direction. The thickness t7 of the well layer 54d is preferably at least 6 nm and less than 15 nm. According to the modification of the third embodiment, it is possible to inhibit crystal growth of the well layer 54d from being difficult by having the major surface of the (11-22) plane dissimilarly to a case where the active layer 54 has a major surface of a non-polar plane such as an m-plane ((1-100) plane) or an a-plane ((11-20) plane), whereby it is possible to suppress increase in the number of crystal defects resulting from a large In composition in the active layer 54. InGaN is an example of the “nitride-based semiconductor” in the present invention, and the well layer 54d is an example of the “third well layer” in the present invention.

A semiconductor laser device 300 is so formed that the thickness t7 (about 8 nm) of the well layer 54d having the In composition of 20% in each of the active layers 54 of the blue semiconductor laser elements 350a and 350b shown in FIG. 13 is larger (t7>t6) than the thickness t6 (about 2.5 nm) of the well layers 34b of each of the active layers 34 of the green semiconductor laser elements 330a to 330c shown in FIG. 12. In the modification of the third embodiment, the thickness of the well layer in the active layer is preferably no more than about 10 nm in a point of suppressing formation of crystal defects in the case where the In composition is about 20%, while the thickness of the well layer is preferably no more than about 3 nm in the point of suppressing formation of crystal defects in a case where the In composition is about 30%. In a case where each active layer 54 has an MQW structure, a value obtained by adding up the thicknesses of respective well layers of the active layer is preferably within the range of the aforementioned numerical values. The well layers 34b are examples of the “fourth well layer” in the present invention.

The In compositions in n-type optical guiding layers 33c and p-type optical guiding layers 35a of the green semiconductor laser elements 330a to 330c constituting the green semiconductor laser element portion 330 are preferably large as compared with the In compositions in the n-type optical guiding layers 53c and p-type optical guiding layers 55a of the blue semiconductor laser elements 350a and 350b constituting the blue semiconductor laser element portion 350.

The remaining structure and a manufacturing process in the modification of the third embodiment are similar to those in the aforementioned third embodiment.

According to the modification of the third embodiment, as hereinabove described, the green semiconductor laser element portion 330 including the active layers 34 made of InGaN having major surfaces of (11-22) planes is so formed on the surface of the same n-type GaN substrate 331 as the n-type GaN substrate 331 provided with the blue semiconductor laser element portion 350 including the active layers 54 made of InGaN having the major surfaces of the (11-22) planes that piezoelectric fields generated in the active layers 34 and 54 can be reduced as compared with a case where the c-planes ((0001) planes) are set to the major surfaces, whereby inclinations of energy bands in the well layers 34b of the active layers 34 and the well layers 54b of the active layers 54 resulting from the piezoelectric fields can be reduced. Thus, the quantities of changes (fluctuation widths) in lasing wavelengths of the blue semiconductor laser element portion 350 and the green semiconductor laser element portion 330 can be more reduced, whereby reduction in yield of the semiconductor laser device 300 comprising the blue semiconductor laser element portion 350 and the green semiconductor laser element portion 330 formed on the surface of the same n-type GaN substrate 331 can be suppressed. Further, the quantities of changes (fluctuation widths) in the lasing wavelengths of the blue semiconductor laser element portion 350 and the green semiconductor laser element portion 330 with respect to the quantities of changes in carrier densities in the active layers 34 and 54 can be more reduced due to the small piezoelectric fields. Thus, it is possible to suppress difficulty in controlling hues of the blue semiconductor laser element portion 350 and the green semiconductor laser element portion 330. Further, luminous efficiency of the blue semiconductor laser element portion 350 and the green semiconductor laser element portion 330 can be improved due to the small piezoelectric fields.

According to the modification of the third embodiment, the quantities of changes in the lasing wavelengths of the blue semiconductor laser element portion 350 and the green semiconductor laser element portion 330 can be reduced since the piezoelectric fields are small in the (11-22) planes as compared with other semipolar planes. Further, semiconductor layers (active layers 34 and 54) having major surfaces of (11-22) planes can be easily formed by setting the (11-22) planes to the major surfaces as compared with a case where non-polar planes such as m-lanes ((1-100) planes) or a-planes ((11-20) planes) which are planes perpendicular to c-planes ((0001) planes) are set to the major surfaces.

According to the modification of the third embodiment, the thickness t7 (about 8 nm: see FIG. 13) of the well layer 54d, having a compressive strain, of each active layer 54 of the blue semiconductor laser element portion 350 is rendered larger (t7>t6) than the thickness t6 (about 2.5 nm: see FIG. 12) of the well layer 34b, having a compressive strain, of each active layer 34 of the green semiconductor laser element portion 330, whereby formation of crystal defects can be suppressed in the well layer 34b easily forming crystal defects due to the large In composition.

According to the modification of the third embodiment, the well layer 54d of each active layer 54 of the blue semiconductor laser element portion 350 is formed to be made of InGaN whose In composition is no more than about 20% while the thickness t7 (about 8 nm) of the well layer 54d is set to at least about 6 nm and not more than about 15 nm, and the well layers 34b of the active layers 34 of the green semiconductor laser element portion 330 are formed to be made of InGaN whose In composition is larger than about 20% while the thickness t6 (about 2.5 nm) of the well layers 34b is set to less than about 6 nm, whereby formation of crystal defects can be reliably suppressed in the well layers 54d of the blue semiconductor laser element portion 350 and the well layers 34b of the green semiconductor laser element portion 330.

According to the modification of the third embodiment, the n-type GaN substrate 331 is formed to have the major surface of the (11-22) plane, whereby the blue semiconductor laser element portion 350 including the active layers 54 having the major surfaces of nonpolar planes and the green semiconductor laser element portion 330 including the active layers 34 having the major surfaces of nonpolar planes can be easily formed by simply forming semiconductor layers on the n-type GaN substrate 331 having the same major surface of the (11-22) plane as the active layers 54 of the blue semiconductor laser element portion 350 and the active layers 34 of the green semiconductor laser element portion 330.

According to the modification of the third embodiment, the active layers 34 of the green semiconductor laser element portion 330 have SQW structures, whereby the active layers 34 can be inhibited from departing from layered structures due to excessive reduction of the thickness t6 (see FIG. 12) of the well layers 34b of the active layers 34 as compared with a case where the active layers 34 have MQW structures.

According to the modification of the third embodiment, the active layers 34 and 54 have the major surfaces of the (11-22) planes, so that it is possible to inhibit crystal growth in the active layers 34 and 54 from being difficult by setting the (11-22) planes to the major surfaces dissimilarly to a case where non-polar planes such as m-planes ((1-100) planes) or a-planes ((11-20) planes) among nonpolar planes are set to the major surfaces, whereby increase in the number of crystal defects resulting from large In compositions can be suppressed in the active layers 34 and 54.

According to the modification of the third embodiment, the (11-22) planes which are semipolar planes have planes inclined by about 58° from the c-planes ((0001) planes) toward the [1]-20] direction, whereby an optical gain of the blue semiconductor laser element portion 350 including the active layers 54 having the major surfaces of the (11-22) planes among the semipolar planes and an optical gain of the green semiconductor laser element portion 330 including the active layers 34 having the major surfaces of the (11-22) planes among the semipolar planes can be more increased. The remaining effects in the modification of the third embodiment are similar to those of the aforementioned third embodiment.

### Fourth Embodiment

FIGS. 14 to 17 are plan views and sectional views showing the structure of a semiconductor laser device according to a fourth embodiment of the present invention. First, referring to FIGS. 14 to 17, a case of constituting an RGB three-wavelength semiconductor laser element portion 490 by bonding the red semiconductor laser element 210 employed in the aforementioned second embodiment onto the surface of the two-wavelength semiconductor laser element portion 370 employed in the aforementioned third embodiment is described in this fourth embodiment. FIG. 15 shows a section taken along the line 4000-4000 in FIG. 14. FIG. 16 shows a section taken along the line 4100-4100 in FIG. 14.

In a semiconductor laser device 400 according to the fourth embodiment of the present invention, the RGB three-wavelength semiconductor laser element portion 490 is fixed onto the upper surface of a protruding block 206, as shown in FIG. 14.

According to the fourth embodiment, it is required to adjust output power ratios of the aforementioned three types of semiconductor laser elements in terms of watts in the RGB three-wavelength semiconductor laser element portion 490 to red:green:blue=9.2:9.9:7.2, in order to obtain white light with a red beam of about 635 nm, a green beam of about 520 nm and a blue beam of about 480 nm.

Therefore, the RGB three-wavelength semiconductor laser element portion 490 is constituted of the red semiconductor laser element 210 (output power: about 350 mW) employed in the aforementioned second embodiment and the two-wavelength semiconductor laser element portion 370 employed in the aforementioned third embodiment, as shown in FIG. 15.

According to the fourth embodiment, the red semiconductor laser element 210 having a width of about 100 μm in a direction B is bonded through an insulating film 480 made of SiO₂ formed on the surface of the two-wavelength semiconductor laser element portion 370 having a width of about 400 μm in the direction B and a conductive adhesive layer 3 made of AuSn solder or the like in the RGB three-wavelength semiconductor laser element portion 490, as shown in FIG. 15. The RGB three-wavelength semiconductor laser element portion 490 is arranged on that position upon a base 491 which is deviated slightly closer to one side (B2 side) from a substantially central portion in the direction (direction B) along which the semiconductor laser elements of respective colors are arrayed, as shown in FIG. 14.

As shown in FIG. 17, the insulating film 480 is so formed that a part of a region (wire bonding region 357a) on an A1 side of a p-side pad electrode 357 of a blue semiconductor laser element portion 350 on a side of an emitting direction (direction A1) of laser beams and a part of region (region in the vicinity of an end portion on a B2 side) of a p-side pad electrode 337 of a green semiconductor laser element portion 330 are exposed. An electrode layer 481 made of Au is formed on a prescribed region of the blue semiconductor laser element portion 350 in the vicinity of an end portion on a side (direction A2) opposite to the emitting direction of the laser beams, to cover the insulating film 480. Thus, in the red semiconductor laser element 210 (see FIG. 16), a p-side pad electrode 17 is partly electrically connected with the electrode layer 481 through the conductive adhesive layer 3 in a region opposed to the electrode layer 481 in the vertical direction (direction C). The electrode layer 481 is so formed that an end region (wire bonding region 481a) on a side (B1 side) provided with the blue semiconductor laser element portion 350 as viewed from the front surface (see FIG. 16) is exposed on a side portion (B1 side) of the red semiconductor laser element 210.

The red semiconductor laser element 210 is connected to a lead terminal 202 through a metal wire 471 wire-bonded to the wire bonding region 481a of the electrode layer 481. The green semiconductor laser element portion 330 of the two-wavelength semiconductor laser element portion 370 is connected to a lead terminal 203 through a metal wire 472 wire-bonded to the wire bonding region 337a of the p-side pad electrode 337. The blue semiconductor laser element portion 350 is connected to a lead terminal 201 through a metal wire 473 wire-bonded to the wire bonding region 357a of the p-side pad electrode 357. An n-side electrode 18 of the red semiconductor laser element 210 is connected to the base 491 through a metal wire 474. The remaining structure of the semiconductor laser device 400 according to the fourth embodiment is similar to that of the aforementioned second embodiment.

A manufacturing process for the semiconductor laser device 400 according to the fourth embodiment is now described with reference to FIGS. 14 to 17.

In the manufacturing process for the semiconductor laser device 400 according to the fourth embodiment, the red semiconductor laser element 210 in a wafer state provided with a ridge 20 every distance of about 400 μm and the two-wavelength semiconductor laser element portion 370 in a wafer state are prepared by a manufacturing process similar to those in the aforementioned second and third embodiments.

Thereafter the insulating film 480 is formed to cover the upper surface of a current blocking layer 376 (see FIG. 16) in a cavity direction (direction A) while leaving the wire bonding region 357a (B1 side) of the p-side pad electrode 357 and the wire bonding region 337a (B2 side) of the p-side pad electrode 337, as shown in FIG. 17. Thereafter the electrode layer 481 having the wire bonding region 481a is formed on that side of the upper surface of the insulating film 480 excluding the p-side pad electrode 357 on which the blue semiconductor laser element portion 350 is formed.

Thereafter the RGB three-wavelength laser element portion 490 in a wafer state is formed by bonding the wafer provided with the two-wavelength semiconductor laser element portion 370 and the wafer provided with the red semiconductor laser element 210 to each other with the conductive adhesive layer 3 while opposing the same to each other. Thereafter the wafer provided with the red semiconductor laser element 210 is partly etched so that the width is about 100 μm. Thereafter a plurality of chips of the RGB three-wavelength laser element portion 490 (see FIG. 14) are formed by cleaving the wafer provided with the RGB three-wavelength laser element portion 490 into a bar to have a prescribed cavity length while performing element division in the cavity direction.

Thereafter the RGB three-wavelength laser element portion 490 is formed by fixing the RGB three-wavelength laser element portion 490 to the base 491 through a conductive adhesive layer (not shown) while pressing the former against the latter, as shown in FIG. 14. Thereafter the electrode layers (wire bonding regions) and the lead terminals are connected with each other by the respective metal wires. Thus, the semiconductor laser device 400 according to the fourth embodiment is formed.

According to the fourth embodiment, as hereinabove described, the red semiconductor laser element 210 is so bonded onto the surface of the two-wavelength semiconductor laser element portion 370 that laser beam emitting portions of the two-wavelength semiconductor laser element portion 370 and a laser beam emitting portion of the red semiconductor laser element 210 can be parallelly arranged at prescribed intervals in a bonding direction (direction C) and rendered close to each other as compared with a case where the two-wavelength semiconductor laser element portion 370 formed by increasing the number (five in total) of the laser beam emitting portions in a transverse rank manner since the required number is large and the red semiconductor laser element 210 are arranged in a linear manner (arranged on the base 491 in a transverse in-line direction, for example), whereby the RGB three-wavelength semiconductor laser element portion 490 can be so arranged that a plurality of laser beam emitting portions concentrate on a central region of a package (base 491). Thus, a plurality of laser beams emitted from the RGB three-wavelength semiconductor laser element portion 490 can be rendered close to an optical axis of an optical system, whereby the semiconductor laser device 400 and the optical system can be easily adjusted. The remaining effects of the fourth embodiment are similar to those of the aforementioned first embodiment.

### Fifth Embodiment

A fifth embodiment of the present invention is described with reference to FIGS. 19 to 20. FIG. 20 shows a detailed structure of a monolithic two-wavelength semiconductor laser element portion 570 shown in FIG. 19 while inverting the vertical direction (direction C1 and direction C2) from FIG. 19.

In a semiconductor laser device 500 according to the fifth embodiment of the present invention, an RGB three-wavelength semiconductor laser element portion 590 consisting of the two-wavelength semiconductor laser element portion 570 and a red semiconductor laser element 210 is bonded onto the upper surface of a base 591 made of AlN or the like by a junction-down system through conductive adhesive layers 4 (4a and 4b) made of AuSn solder or the like, as shown in FIG. 19. The conductive adhesive layers 4a and 4b are examples of the “first fusion layer” and the “second fusion layer” in the present invention respectively, and the base 591 is an example of the “support base” in the present invention.

In blue semiconductor laser elements 550a and 550b constituting a blue semiconductor laser element portion 550 and arranged in line in a direction (direction B) where laser elements are arrayed through a recess portion 6, an n-type GaN layer 512 made of Ge-doped GaN having a thickness of about 1 μm, respective n-type cladding layers 513 made of n-type AlGaN each having a thickness of about 2 μm, respective active layers 514 in which quantum well layers and barrier layers made of InGaN are alternately stacked and respective p-type cladding layers 515 made of p-type AlGaN each having a thickness of about 0.3 μm are formed on an upper surface 331a of an n-type GaN substrate 331, as shown in FIG. 20. The active layers 514 and the p-type cladding layers 515 are examples of the “fifth active layer” and the “first semiconductor layer” in the present invention respectively.

The p-type cladding layers 515 have projecting portions 515a and planar portions extending on both sides (direction B) of the projecting portions 515a. Ridges 520 for constituting waveguides are formed by the projecting portions 515a of these p-type cladding layers 515. P-side ohmic electrodes 516 consisting of Cr layers and Au layers successively from the side closer to the p-type cladding layers 515 are formed on the ridges 520. A current blocking layer 517 made of SiO₂ is formed to cover the planar portions of the p-type cladding layers 515 and the side surfaces of the ridges 520. A p-side pad electrode 518 made of Au or the like is formed on the upper surfaces of the ridges 520 and the current blocking layer 517. The p-side pad electrode 518 is an example of the “first pad electrode” in the present invention.

A green semiconductor laser element portion 530 is formed on the other side (B1 side) of the upper surface of the n-type GaN substrate 331 from the blue semiconductor laser element portion 550 through a recess portion 8. In each of green semiconductor laser element portions 530a, 530b and 530c arranged in line in the direction (direction B) where the laser elements are arrayed through recess portions 7 in the green semiconductor laser element portion 530, an n-type GaN layer 512 having a thickness of about 1 μm, n-type cladding layers 533 made of n-type AlGaN each having a thickness of about 3 μm, active layers 534 in which quantum well layers and barrier layers made of InGaN are alternately stacked and p-type cladding layers 535 made of p-type AlGaN each having a thickness of about 0.45 μm are formed on the upper surface (on the upper surface 331a) of the n-type GaN substrate 331. The active layers 534 and the p-type cladding layers 535 are examples of the “sixth active layer” and the “second semiconductor layer” in the present invention respectively.

The p-type cladding layers 535 have projecting portions 535a and planar portions extending on both sides (direction B) of the projecting portions 535a. Ridges 540 for constituting waveguides are formed by the projecting portions 535a of these p-type cladding layers 535. P-side ohmic electrodes 536 consisting of Cr layers and Au layers successively from the side closer to the p-type cladding layers 535 are formed on the ridges 540. The current blocking layer 517 extending from the blue semiconductor laser element portion 550 is formed to cover the planar portions of the p-type cladding layers 535 and the side surfaces of the ridges 540. A p-side pad electrode 538 made of Au or the like is formed on the upper surfaces of the ridges 540 and the current blocking layer 517. The p-side pad electrode 538 is an example of the “second pad electrode” in the present invention.

The p-side ohmic electrodes 516 (first ohmic electrode layers) and the p-side pad electrode 518 (first pad electrode) are examples of the “first electrode” in the present invention, and the p-side ohmic electrodes 536 (second ohmic electrode layers) and the p-side pad electrode 538 (second pad electrode) are examples of the “second electrode” in the present invention. The semiconductor laser device 500 comprises the first ohmic electrode layers between the first semiconductor layer and the first pad electrode, and comprises the second ohmic electrode layers between the second semiconductor layer and the second pad electrode, whereby p-side contact resistance of the blue semiconductor laser element portion 550 and the green semiconductor laser element portion 530 can be reduced. An n-side electrode 539 in which a Ti layer, a Pt layer and an Au layer are successively stacked from the side closer to the n-type GaN substrate 331 is formed on a lower surface 331b of the n-type GaN substrate 331.

As shown in FIG. 18, the length of the base 591 in a cavity direction (direction A) is rendered larger than a cavity length of the two-wavelength semiconductor laser element portion 570. On the upper surface of the base 591 (see FIG. 19), wiring electrodes 594 and 593 made of Au described later are formed on positions corresponding to the p-side pad electrodes 518 and 538 respectively. The wiring electrodes 593 and 594 extend in the direction A (see FIG. 19) in the form of strips and are formed to be longer than the cavity length of the two-wavelength semiconductor laser element portion 570. Therefore, the blue semiconductor laser element portion 550 and the green semiconductor laser element portion 530 of the two-wavelength semiconductor laser element portion 570 are formed to be connected with an external portion through metal wires wire-bonded to those regions of the wiring electrodes 593 and 594 to which the two-wavelength semiconductor laser element portion 570 is not bonded, as shown in FIG. 19.

According to the fifth embodiment, the semiconductor laser device 500 is so formed that the thickness t2 of semiconductor element layers in the green semiconductor laser element portion 530 from the lower surface 331b of the n-type GaN substrate 331 to the upper surfaces of the projecting portions 535a of the p-type cladding layers 535 is larger (t1<t2, and t2−t1=about 1.2 μm) than the thickness t1 of semiconductor element layers in the blue semiconductor laser element portion 550 from the lower surface 331b of the n-type GaN substrate 331 to the upper surfaces of the projecting portions 515a of the p-type cladding layers 515 when comparing the blue semiconductor laser element portion 550 and the green semiconductor laser element portion 530 with each other, as shown in FIG. 20. Further, the thickness t3 of the blue semiconductor laser element portion 550 from the lower surfaces of the p-side ohmic electrodes 516 (upper surfaces of the projecting portions 515a) to the upper surface of the p-side pad electrode 518 is rendered larger (t3>t4, and t3−t4=about 1.2 μm) than the thickness t4 of the green semiconductor laser element portion 530 from the lower surfaces of the p-side ohmic electrodes 536 (upper surfaces of the projecting portions 535a) to the p-side pad electrode 538. Thus, the thickness (t1+t3) of the blue semiconductor laser element portion 550 from the lower surface 331b of the n-type GaN substrate 331 to the lower surface of the conductive adhesive layer 4 (4a) and the thickness (t2+t4) of the green semiconductor laser element portion 530 from the lower surface 331b of the n-type GaN substrate 331 to the lower surface of the conductive adhesive layer 4 (4b) are substantially identical to each other. The “thickness” in the fifth embodiment denotes the thickness of the electrode and the fusion layer between each of the upper surfaces of projecting portions (ridges) and the lower surface of the base 591.

According to the fifth embodiment, the thickness t13 of the p-side pad electrode 518 is rendered larger (t13 t14) than the thickness t14 of the p-side pad electrode 538, in addition to the aforementioned relation of t3>t4. Further, the thickness of the p-type cladding layers 535 of the green semiconductor laser element portion 530 is rendered lager than the thickness of the p-type cladding layers 515 of the blue semiconductor laser element portion 550, and the thickness of the n-type cladding layers 533 of the green semiconductor laser element portion 530 is rendered larger than the thickness of the n-type cladding layers 513 of the blue semiconductor laser element portion 550.

According to the fifth embodiment, the upper surface (surface on a C2 side) of the p-side pad electrode 518 and the upper surface (C2 side) of the p-side pad electrode 538 are aligned on substantially identical planes (shown by a broken line). Thus, the two-wavelength semiconductor laser element portion 570 is fixed to the base 591 through the conductive adhesive layers 4a and 4b having substantially identical thicknesses in a direction C. The lower surface 331b is an example of the “surface of another side” in the present invention, and the upper surfaces of the projecting portions 515a and the upper surfaces of the projecting portions 535a are examples of the “surface of the first semiconductor layer” and the “surface of the second semiconductor layer” in the present invention respectively.

As shown in FIGS. 18 and 19, a wiring electrode 592 made of Au is formed on a region of the upper surface of the base 591 to which the red semiconductor laser element 210 is bonded. As shown in FIG. 18, the p-side pad electrode 217 (see FIG. 19) and the wiring electrode 592 are bonded to each other through a conductive adhesive layer 1, and the red semiconductor laser element 210 is bonded onto the upper surface of the base 591 by a junction-down system. The wiring electrode 592 is connected to a lead terminal 202 through a wire-bonded metal wire 595. An n-side electrode 218 is electrically connected to a protruding block 206 through a wire-bonded metal wire 596. The wiring electrode 593 electrically connected to the p-side pad electrode 538 (see FIG. 19) of the green semiconductor laser element portion 530 is connected to a lead terminal 201 through a wire-bonded metal wire 597, while the wiring electrode 594 electrically connected to the p-side pad electrode 518 (see FIG. 19) of the blue semiconductor laser element portion 550 is connected to a lead terminal 203 through a wire-bonded metal wire 598. The two-wavelength semiconductor laser element portion 570 is electrically connected to the protruding block 206 through a metal wire 599 wire-bonded to the n-side electrode 539. Thus, the semiconductor laser device 500 is formed in a state (cathode-common) where the p-side pad electrodes (217, 518 and 538) of the respective semiconductor laser elements are connected to the lead terminals insulated from each other while the n-side electrodes (218 and 539) are connected to a common cathode terminal. As shown in FIG. 18, the semiconductor laser device 500 is so formed that laser beams of respective colors are emitted from a cavity facet on the A1 side of the RGB three-wavelength semiconductor laser element portion 590.

A manufacturing process for the semiconductor laser device 500 according to the fifth embodiment is now described with reference to FIGS. 18 to 26.

In the manufacturing process for the semiconductor laser device 500 according to the fifth embodiment, a mask 541 made of SiO₂ for selective growth is first patterned on the upper surface 331a of the n-type GaN substrate 331 by photolithography, as shown in FIG. 21. The mask 541 is patterned to extend in the direction A (direction perpendicular to the plane of the paper) at a prescribed interval in the direction B. Thereafter n-type cladding layers 513, active layers 514 and p-type cladding layers 515 are selectively grown on the upper surface 331a of the n-type GaN substrate 331 exposed from openings 541a of the mask 541 by MOCVD for forming semiconductor element layers 510c, as shown in FIG. 22.

Thereafter the mask 541 is removed. Then, a mask 542 covering prescribed regions of the upper surface 331a of the n-type GaN substrate 331 and the overall surfaces of the semiconductor element layers 510c each constituting the blue semiconductor laser element portion 550 is patterned by photolithography, as shown in FIG. 23. In this state, an n-type cladding layer 533, an active layer 534 and a p-type cladding layer 535 are selectively grown on the upper surface 331a of the n-type GaN substrate 331 exposed from openings 542a of the mask 542 to form a semiconductor element layer 530d. At this time, the semiconductor element layer 530d is so formed that the thickness thereof is larger by about 1.2 μm than the semiconductor element layers 510c each constituting the blue semiconductor laser element portion 550. Thereafter the mask 542 is removed. Thus, the semiconductor element layers 510c and 530c are formed through the recess portion 8.

Then, the recess portion 6 whose bottom surface reaches the n-type GaN layer 512 for separating each semiconductor element layer 510c into the blue semiconductor laser elements 550a and 550b is formed while the recess portions 7 whose bottom surfaces reach the n-type GaN layer 512 for separating the semiconductor element layer 530c into the green semiconductor laser elements 530a, 530b and 530c are formed, and the p-side ohmic electrodes 516 and 536 are thereafter formed on the surfaces of the p-type cladding layers 515 and 535 respectively, as shown in FIG. 24. Thereafter a resist film (not shown) extending in the direction A (direction perpendicular to the plane of the paper) in a striped manner is patterned on the p-side ohmic electrodes 516 and 536 by photolithography while the resist film is employed as a mask to perform dry etching, thereby forming two ridges 520 and three ridges 540 on the portions of the p-type cladding layers 515 and 535 respectively. Thus, an element structure of the blue semiconductor laser element portion 550 and an element structure of the green semiconductor laser element portion 530 are formed on the n-type GaN substrate 331 (upper surface 331a) at a prescribed interval in the width direction (direction B) the direction B of the elements.

Thereafter the current blocking layer 517 is formed by plasma CVD or the like to cover the surfaces of the semiconductor element layers 510c and 530d (including the side surfaces and the bottom surfaces of the respective recess portions 7 and 8) other than the upper surfaces (surfaces on the C1 side) of the p-side ohmic electrodes 516 and 536, as shown in FIG. 25.

Thereafter a resist film 543 is patterned by photolithography to cover prescribed regions of the surface of the current blocking layer 517. At this time, the resist film 543 is so patterned that only the prescribed regions of the current blocking layer 517 continuous to portions above the ridges 520 (540) and both sides of the ridges 520 (540) are exposed, as shown in FIG. 25. The resist film 543 is formed correspondingly to the thicknesses of the semiconductor element layers 510c and 530d in the height direction (direction C), whereby the same is so formed that heights from the upper surface 331a of the n-type GaN substrate 331 to the upper surface of the resist film 543 are different from each other in the element structure region of the blue semiconductor laser element portion 550 and the element structure region of the green semiconductor laser element portion 530. In this state, Au metal layers 545 (545a and 545b) are deposited in openings 543a (portions where the p-side ohmic electrodes 516 and 536 are exposed) of the resist film 543 by vacuum evaporation. Thus, the openings 543a are substantially completely filled up with the Au metal layers 545.

Then, the resist film 543 (see FIG. 25) is removed, and the thicknesses of the Au metal layers 545 are thereafter adjusted by chemical mechanical polishing (CMP) so that the upper surfaces (surfaces on the C1 side) of the Au metal layers 545 are substantially flush with each other, as shown in FIG. 26. At this time, the polishing is first started toward the direction C2 from the upper surface of the Au metal layer 545b on the side provided with the green semiconductor laser element portion 530. Then, the CMP step is terminated when the height H1 from the upper surface 331a of the n-type GaN substrate 331 to the upper surface of the Au metal layer 545b is substantially equal to the height H2 from the upper surface 331a of the n-type GaN substrate 331 to the upper surface of the Au metal layer 545a. At this point of time, the Au metal layer 545a forms the p-side pad electrode 518 (thickness t13), and the Au metal layer 545b forms the p-side pad electrode 538 (thickness t14). Thus, the two-wavelength semiconductor laser element portion 570 in which the heights from the lower surface 331b of the n-type GaN substrate 331 to the upper surfaces of the p-side pad electrodes 518 (538) are substantially equal to each other is obtained. Then, the lower surface 331b of the n-type GaN substrate 331 is so polished that the n-type GaN substrate 331 has a thickness of about 100 μm, and the n-side electrode 539 is thereafter formed on the lower surface 331b of the n-type GaN substrate 331. Thus, the two-wavelength semiconductor laser element portion 570 in a wafer state is formed.

Thereafter the wafer is cleaved into bars in the direction B to have a cavity length of about 600 μm in the direction A and element-divided along the direction A (direction perpendicular to the plane of the paper) on positions of broken lines 800 (see FIG. 26), whereby a plurality of chips of the two-wavelength semiconductor laser element portion 570 (see FIG. 18) are formed.

On the other hand, the base 591 provided on the surface thereof with the wiring electrodes 592, 593 and 594 in the form of strips and formed in a prescribed shape is prepared, as shown in FIG. 19. At this time, the conductive adhesive layer 1 having a thickness of about 1 μm is previously formed on the surface of the wiring electrode 592, while the conductive adhesive layers 4 having a thickness of about 1 μm are previously formed on the surfaces of the wiring electrodes 593 and 594. Then, the two-wavelength semiconductor laser element portion 570 and the base 591 are bonded to each other by thermocompression bonding while opposing the same to each other, as shown in FIG. 19. At this time, the two-wavelength semiconductor laser element portion 570 and the base 591 are so bonded to each other that the p-side pad electrode 518 corresponds to the wiring electrode 592 while the p-side pad electrode 538 corresponds to the wiring electrode 593. Further, the two-wavelength semiconductor laser element portion 570 and the base 591 are so bonded to each other that an end portion on the A1 side of the base 591 and a cavity facet on the A1 side (light-emitting side) of the two-wavelength semiconductor laser element portion 570 are arranged on substantially identical planes, as shown in FIG. 18.

The red semiconductor laser element 210 and the base 591 are bonded to each other by thermocompression bonding while opposing the same to each other. At this time, the red semiconductor laser element 210 and the base 591 are so bonded to each other that a p-side pad electrode 17 is opposed to the wiring electrode 592. Further, the red semiconductor laser element 210 and the base 591 are so bonded to each other that the end portion on the A1 side of the base 591 and a cavity facet on the A1 side (light-emitting side) of the red semiconductor laser element 210 are arranged on substantially identical planes, as shown in FIG. 18.

Finally, a lower surface 591a (see FIG. 19) of the base 591 is bonded to the upper surface of the protruding block 206 (see FIG. 18), while the metal wires 596, 599, 596, 597 and 598 are wire-bonded to and electrically connected with the n-side electrodes 218 and 539 and the wiring electrodes 592 to 594 respectively. Thus, the semiconductor laser device 500 (see FIG. 18) according to the fifth embodiment is formed.

According to the fifth embodiment, as hereinabove described, the thickness t3 from the lower surfaces of the p-side ohmic electrodes 516 (upper surfaces of the projecting portions 515a) to the upper surface of the p-side pad electrode 518 and the thickness t4 from the lower surfaces of the p-side ohmic electrodes 536 (upper surfaces of the projecting portions 535a) to the p-side pad electrode 538 have the relation of t3>t4, so that, even if a difference is caused between the thickness t1 of the blue semiconductor laser element portion 550 from the lower surface 331b of the n-type GaN substrate 331 to the upper surfaces of the projecting portions 515a of the p-type cladding layers 515 and the thickness t2 of the green semiconductor laser element portion 530 from the lower surface 331b of the n-type GaN substrate 331 to the upper surfaces of the projecting portions 535a of the p-type cladding layers 535, a difference between the thickness (t1+t3) of the blue semiconductor laser element 550 and the thickness (t2+t4) of the green semiconductor laser element portion 530 can be more reduced since the difference in the thicknesses (difference between the thickness t3 and the thickness t4 in FIG. 18) is provided on the portions of the p-side electrode layers. In other words, even if a difference is caused between the thicknesses t1 and t2 of the semiconductor element layers in the blue semiconductor laser element 550 and the green semiconductor laser element portion 530, the difference (difference between the thickness t1 and the thickness t2) can be properly adjusted through the difference in the thicknesses (difference between the thickness t3 and the thickness t4) of the p-side electrode layers. Thus, the thicknesses of the blue semiconductor laser element 550 and the green semiconductor laser element portion 530 including the common n-type GaN substrate 331 can be substantially uniformized and hence it is unnecessary to make the conductive adhesive layers 4 absorb the difference between the thicknesses of the semiconductor laser elements when bonding this semiconductor laser device 500 (two-wavelength semiconductor laser element portion 570) to the base 591 through the conductive adhesive layers 4 in a junction-down system, whereby the conductive adhesive layers 4 (4a and 4b) can be suppressed to the minimum necessary quantities. Consequently, such an inconvenience is suppressed that an electrical short circuit is caused between the laser elements due to excessive conductive adhesive layers 4 jutting out after bonding, whereby the yield in formation of the semiconductor laser device 500 can be improved.

According to the fifth embodiment, the thickness t13 of the p-side pad electrode 518 and the thickness t14 of the p-side pad electrode 538 have the relation of t13 t14, whereby the difference in the thicknesses of the blue semiconductor laser element 550 and the green semiconductor laser element portion 530 can be reduced. Thus, the conductive adhesive layers 4 can be suppressed to the minimum necessary quantities when bonding this semiconductor laser device 500 to the base 591 in the junction-down system.

According to the fifth embodiment, the thickness of the conductive adhesive layer 4a and the thickness of the conductive adhesive layer 4b are substantially identical to each other, whereby the used conductive adhesive layers 4 can be both suppressed to the minimum necessary quantities in bonded portions of the blue semiconductor laser element 550 and the green semiconductor laser element portion 530 and the base 591.

According to the fifth embodiment, the semiconductor laser device 500 is so formed that the p-side pad electrodes 518 and 538 are pad electrodes in contact with the p-side ohmic electrodes 516 and the p-side ohmic electrodes 536 respectively, whereby the thicknesses of the blue semiconductor laser element 550 and the green semiconductor laser element portion 530 formed on the surface (on the upper surface 331a) of the common n-type GaN substrate 331 can be easily uniformized.

According to the fifth embodiment, the thickness of the p-type cladding layers 535 of the green semiconductor laser element portion 530 is rendered larger than the thickness of the p-type cladding layers 515 of the blue semiconductor laser element portion 550, whereby a light confinement effect of the p-type cladding layers of the green semiconductor laser elements, tending to be weaker than a light confinement effect of the p-type cladding layers in the blue semiconductor laser elements in general, can be improved. The remaining effects of the fifth embodiment are similar to those of the aforementioned first embodiment.

The embodiments disclosed this time must be considered as illustrative in all points and not restrictive. The range of the present invention is shown not by the above description of the embodiments but by the scope of claims for patent, and all modifications within the meaning and range equivalent to the scope of claims for patent are included.

For example, the lasing wavelengths, the rated output power and the number (number of the laser beam emitting portions) of each of the green semiconductor laser elements 30, the blue semiconductor laser elements 50 and the red semiconductor laser element 10 are not restricted to the described ones in each of the aforementioned first to fifth embodiments, but the lasing wavelength, the rated output power and the number of each of the green semiconductor laser elements 30, the blue semiconductor laser elements 50 and the red semiconductor laser element 10 described in each embodiment may be applied also to other embodiments, for example. For example, while the example of forming the semiconductor laser device 100 so that the numbers n1, n2 and n3 of the green semiconductor laser elements 30, the blue semiconductor laser elements 50 and the red semiconductor laser element 10 constituting the RGB three-wavelength semiconductor laser element portion 90 are three, two and one respectively has been shown in the aforementioned first embodiment, the present invention is not restricted to this. In the present invention, the numbers may simply be n1>n2>n3, and the semiconductor laser device 100 may be so formed that the numbers of the green semiconductor laser elements 30, the blue semiconductor laser elements 50 and the red semiconductor laser element 10 are four, two and one respectively, for example. Alternatively, the semiconductor laser device 100 may have a plurality of red semiconductor laser elements 10, and may be so formed that the numbers of the green semiconductor laser elements 30, the blue semiconductor laser elements 50 and the red semiconductor laser elements 10 are six, four and two respectively, for example. Further alternatively, the RGB three-wavelength semiconductor laser element portion may be constituted of three green semiconductor laser elements in which each laser beam emitting portion has an output power of about 90 mW, two blue semiconductor laser elements similarly having an output power of about 200 mW and one red semiconductor laser element having an output power of about 800 mW, or the RGB three-wavelength semiconductor laser element portion may be constituted of three green semiconductor laser elements in which each laser beam emitting portion has an output power of about 90 mW, four blue semiconductor laser elements similarly having an output power of about 150 mW and one red semiconductor laser element having an output power of about 800 mW, for example.

While the example of forming the RGB three-wavelength laser element portion 490 to obtain white light with the red beam of about 635 nm, the green beam of about 520 nm and the blue beam of about 480 nm has been shown in the aforementioned fourth embodiment, the present invention is not restricted to this. In other words, the RGB three-wavelength semiconductor laser element portion may be formed with a red beam of about 655 nm, a green beam of about 520 nm and a blue beam of about 480 nm, similarly to the aforementioned third embodiment.

While the example of bonding the red semiconductor laser element 210 onto the monolithic two-wavelength semiconductor laser element portion 370 in which the green semiconductor laser element 330 and the blue semiconductor laser element 350 are integrated has been shown in the aforementioned fourth embodiment, in the aforementioned fourth embodiment, the present invention is not restricted to this. In other words, the red semiconductor laser element may be bonded onto the green semiconductor laser elements in the aforementioned second embodiment, or the red semiconductor laser element may be bonded onto the blue semiconductor laser elements in the aforementioned second embodiment.

While the examples of forming the bases (91, 291, 391, 491 and 591) to which the RGB three-wavelength semiconductor laser element portions are bonded by the substrates made of AlN have been shown in the aforementioned first to fifth embodiments, the present invention is not restricted to this. According to the present invention, the base may be constituted of a conductive material consisting of Fe or Cu having excellent thermal conductivity.

While the example of forming the RGB three-wavelength semiconductor laser element portion by ridge-guided semiconductor lasers in which upper cladding layers having ridges are formed on planar active layers in which blocking layers of dielectrics are formed on the side surfaces of the ridges has been shown in each of the aforementioned first to fifth embodiments, the present invention is not restricted to this. In other words, the RGB three-wavelength semiconductor laser element portion may be formed by ridge-guided semiconductor lasers having blocking layers of semiconductors, buried heterostructure (BH) semiconductor lasers or gain-guided semiconductor lasers in which current blocking layers having striped openings are formed on planar upper cladding layers.

While the example of forming the well layers of the active layers of the green semiconductor laser elements to have the thickness of about 3.5 nm has been shown in the aforementioned third embodiment, the present invention is not restricted to this. For example, the well layers of the active layers of the green semiconductor laser elements may be formed to have a thickness of at least 3 nm.

While the example of forming all well layers (one well layer) of multiple well layers constituting the MQW structure of the blue semiconductor laser elements to have the thickness of about 3 nm has been shown in the aforementioned third embodiment, the present invention is not restricted to this. In other words, the thickness of the well layers of the active layers of the blue semiconductor laser elements is not particularly restricted. The thickness of the well layers of the active layers of the blue semiconductor laser elements is preferably smaller than the thickness of the well layers of the active layers of the green semiconductor laser elements.

While the example of forming the active layers of the blue semiconductor laser elements to have the MQW structures and forming the active layers of the green semiconductor laser elements to have the SQW structures has been shown in the aforementioned third embodiment, the present invention is not restricted to this. In other words, the active layers of the blue semiconductor laser elements may be formed to have SQW structures, and the active layers of the green semiconductor laser elements may be formed to have MQW structures.

While the example of forming the well layers of the active layers of the green semiconductor laser elements to be made of InGaN having the In composition of 33% has been shown in the aforementioned third embodiment, the present invention is not restricted to this. In other words, the composition of the well layers of the active layers of the green semiconductor laser elements is not particularly restricted. In this case, the well layers of the active layers of the green semiconductor laser elements are preferably formed to be made of InGaN having an In composition of at least 30%.

While the example of employing the (11-22) plane which is the semipolar plane as an example of the nonpolar plane as the surface orientation of the major surfaces of the active layers of the blue semiconductor laser elements and the active layers of the green semiconductor laser elements has been shown in the aforementioned third embodiment, the present invention is not restricted to this. For example, another semipolar plane such as a (11-2×) plane (x=2, 3, 4, 5, 6, 8, 10, −2, −3, −4, −5, −6, −8 or −10) or a (1-10y) plane (y=1, 2, 3, 4, 5, 6, −1, −2, −3, −4, −5 or −6) may be employed as the surface orientation of the major surfaces of the active layers of the blue semiconductor laser elements and the active layers of the green semiconductor laser elements. In this case, the thicknesses of and the In compositions in the active layers of the blue semiconductor laser elements and the active layers of the green semiconductor laser elements are properly changed. The semipolar plane is preferably a plane inclined by at least about 10 degrees and not more than about 70 degrees with respect to a (0001) plane or a (000-1) plane.

While the example of forming the active layers made of InGaN having the major surfaces of the (11-22) planes on the upper surface of the n-type GaN substrate has been shown in each of the aforementioned third embodiment and the modification thereof, the present invention is not restricted to this. For example, the active layers made of InGaN having the major surfaces of the (11-22) planes may be formed on the upper surface of a substrate made of Al₂O₃, SiC, LiAlO₂ or LiGaO₂.

While the example in which the well layers of the blue semiconductor laser elements and the well layers of the green semiconductor laser elements are made of InGaN has been shown in each of the aforementioned third embodiment and the modification thereof, the present invention is not restricted to this. For example, the well layers of the blue semiconductor laser elements and the well layers of the green semiconductor laser elements may be formed to be made of AlGaN, AlInGaN or InAlN. In this case, the thicknesses of and the compositions in the active layers of the blue semiconductor laser elements are properly changed.

While the example in which the barrier layers of the blue semiconductor laser elements and the green semiconductor laser elements are made of InGaN has been shown in each of the aforementioned third embodiment and the modification thereof, the present invention is not restricted to this. For example, the barrier layers of the blue semiconductor laser elements and the green semiconductor laser elements may be formed to be made of GaN.

While the example of forming the active layers made of InGaN having the major surfaces of the (11-22) planes on the n-type GaN substrate having the major surface of the (11-22) plane has been shown in the aforementioned third embodiment, the present invention is not restricted to this. In other words, a sapphire substrate having a major surface of an r-plane ((1-102) plane) on which a nitride-based semiconductor (InGaN, for example) having a major surface of a (11-22) plane, a (1-103) plane or a (1-126) plane is previously grown may be employed.

While the example of forming the active layers (well layers) made of InGaN on the n-type GaN substrate has been shown in each of the aforementioned third embodiment and the modification thereof, the present invention is not restricted to this. In other words, the active layers (well layers) made of InGaN may be formed on an AlₓGa₁₋ₓN substrate. It is possible to suppress spreading of a light intensity distribution in a vertical transverse mode by increasing the Al composition. Thus, it is possible to inhibit the AlₓGa₁₋ₓN substrate from emitting a beam, whereby it is possible to inhibit the laser elements from emitting a plurality of beams of the vertical transverse mode. Alternatively, the active layers (well layers) made of InGaN may be formed on an In_{y}Ga_{1-y}N substrate. Thus, it is possible to reduce strains in the active layers (well layers) by adjusting the In composition in the In_{y}Ga_{1-y}N substrate. In this case, the thicknesses of and the In compositions in the active layers (well layers) of the blue semiconductor laser elements and the thicknesses of and the In compositions in the active layers (well layers) of the green semiconductor laser elements are properly changed individually.

While the example of employing the (11-22) plane which is a semipolar plane as an example of the nonpolar plane as the surface orientation of the major surfaces of the active layers of the blue semiconductor laser elements and the active layers of the green semiconductor laser elements has been shown in each of the aforementioned third embodiment and the modification thereof, the present invention is not restricted to this. According to the present invention, another nonpolar plane (a non-polar plane or a semipolar plane) may be employed as the surface orientation of the major surfaces of the active layers of the blue semiconductor laser elements and the active layers of the green semiconductor laser elements. A non-polar plane such as an a-plane ((11-20) plane) or an en-plane ((1-100) plane) may be employed as the surface orientation of the major surfaces of the active layers of the blue semiconductor laser elements and the active layers of the green semiconductor laser elements, or a semipolar plane such as a (11-2×) plane (x ˜2, 3, 4, 5, 6, 8, 10, −2, −3, −4, −5, −6, −8 or −10) or a (1-10y) plane (y=1, 2, 3, 4, 5, 6, −1, −2, −3, −4, −5 or −6) may be employed.

While the example of employing InGaN as the “nitride-based semiconductor” in the present invention has been shown in the modification of the aforementioned third embodiment, the present invention is not restricted to this. According to the present invention, AlGaN or the like may be employed as the nitride-based semiconductor. In this case, the thicknesses of and the compositions in the active layers of the blue semiconductor laser elements and the active layers of the green semiconductor laser elements are properly changed.

While the example in which the two-wavelength semiconductor laser element portion 570 is bonded to the lower surface of the base 591 in the state where the upper surface position of the p-side pad electrode 518 of the blue semiconductor laser element 550 and the upper surface position of the p-side pad electrode 538 of the green semiconductor laser element portion 530 are substantially identical positions has been shown in the aforementioned fifth embodiment, the present invention is not restricted to this. In other words, the semiconductor laser device 500 may be so formed that the two-wavelength semiconductor laser element 570 is bonded to the lower surface of the base 591 in a state where slight deviation is caused between the upper surface positions of the p-side pad electrodes.

While the example in which the thickness of the blue semiconductor laser element 550 including the n-type GaN substrate 331 is rendered smaller than the thickness of the green semiconductor laser element 530 including the n-type GaN substrate 331 has been shown in the aforementioned fifth embodiment, the present invention is not restricted to this. In other words, the two-wavelength semiconductor laser element may be so formed that the thickness of the blue semiconductor laser element 550 including the n-type GaN substrate 331 is rendered larger than the thickness of the green semiconductor laser element 530 including the n-type GaN substrate 331. In this case, the thickness of the p-side pad electrode 518 of the blue semiconductor laser element 550 is rendered smaller than the thickness of the p-side pad electrode 538 of the green semiconductor laser element portion 530. Thus, the upper surfaces (C2 side) of the p-side pad electrodes 518 and 538 are aligned to be substantially flush with each other, whereby it is possible to fix the two-wavelength semiconductor laser element to the base 591 through conductive adhesive layers having substantially identical thicknesses in the direction C.

While the example of forming the blue semiconductor laser elements and the green semiconductor laser elements on the surface of the n-type GaN substrate has been shown in the aforementioned fifth embodiment, the present invention is not restricted to this. For example, the blue semiconductor laser elements and the green semiconductor laser elements may be formed after forming a separation layer, a common n-type contact layer etc. on the surface of a substrate for growth. A semiconductor laser device in which the “substrate” in the present invention consists of only the n-type contact layer etc. may be formed by bonding this two-wavelength semiconductor laser element to a support base or a red semiconductor laser element and thereafter separating only the substrate for growth. In this case, an n-side electrode is formed on the lower surface of the n-type contact layer after the separation of the substrate for growth. In this case, further, the common n-type contact layer may also serve as an n-type cladding layer of one laser element.

While the example of rendering the thickness of the p-type cladding layers of the green semiconductor laser elements larger than the thickness of the p-type cladding layers of the blue semiconductor laser elements has been shown in the aforementioned fifth embodiment, the present invention is not restricted to this. When the thickness of the blue semiconductor laser elements (thickness from the lower surface of the n-type GaN substrate to the upper surfaces of the p-type cladding layers) is larger than the thickness of the green semiconductor laser elements (thickness from the lower surface of the n-type GaN substrate to the upper surfaces of the p-type cladding layers), for example, the thickness of the p-type cladding layers (first semiconductor layers) of the blue semiconductor laser elements may be rendered larger than the thickness of the p-type cladding layers (second semiconductor layers) of the green semiconductor laser elements.

1. A semiconductor laser device comprising:
a green semiconductor laser element having one or a plurality of laser beam emitting portions;
a blue semiconductor laser element having one or a plurality of laser beam emitting portions; and
a red semiconductor laser element having one or a plurality of laser beam emitting portions, wherein
at least two semiconductor laser elements among said green semiconductor laser element, said blue semiconductor laser element and said red semiconductor laser element have such a relation that the number of said laser beam emitting portions of said semiconductor laser element whose total output power is relatively small is larger than the number of said laser beam emitting portions of said semiconductor laser element, having said plurality of laser beam emitting portions, whose total output power is relatively large, or the number of said semiconductor laser element, having one said laser beam emitting portion, whose output power is relatively large.

2. The semiconductor laser device according to claim 1, having a relation of n1>n2>n3, where n1, n2 and n3 represent the respective numbers of said laser beam emitting portions of said green semiconductor laser element, said blue semiconductor laser element and said red semiconductor laser element.

3. The semiconductor laser device according to claim 1, wherein
said green semiconductor laser element and said blue semiconductor laser element are formed on a substrate common to said green semiconductor laser element and said blue semiconductor laser element.

4. The semiconductor laser device according to claim 1, wherein
said green semiconductor laser element is a monolithic element provided with a plurality of said laser beam emitting portions, while said blue semiconductor laser element is a monolithic element provided with a plurality of said laser beam emitting portions.

5. The semiconductor laser device according to claim 1, wherein
said red semiconductor laser element is bonded to at least either said green semiconductor laser element or said blue semiconductor laser element.

6. The semiconductor laser device according to claim 1, further comprising:
a base to which said green semiconductor laser element, said blue semiconductor laser element and said red semiconductor laser element are bonded, and
a plurality of terminals electrically connected with an external portion and insulated from each other, wherein
said green semiconductor laser element includes electrodes formed on a surface opposite to said base, and
at least two said electrodes of said green semiconductor laser elements among n1 laser beam emitting portions are connected to said respective terminals different from each other, where said n1 represents the number of said laser beam emitting portions of said green semiconductor laser element.

7. The semiconductor laser device according to claim 3, wherein
said green semiconductor laser element includes a first active layer formed on the surface of said substrate and having a major surface of a semipolar plane,
said blue semiconductor laser element includes a second active layer formed on the surface of said substrate and having a major surface of a surface orientation substantially identical to said semipolar plane, and
said first active layer includes a first well layer having a compressive strain and having a thickness of at least 3 nm while said second active layer includes a second well layer having a compressive strain.

8. The semiconductor laser device according to claim 7, wherein
said first well layer is made of InGaN.

9. The semiconductor laser device according to claim 7, wherein
said second well layer is made of InGaN.

10. The semiconductor laser device according to claim 7, wherein
the thickness of said first well layer is larger than the thickness of said second well layer.

11. The semiconductor laser device according to claim 7, wherein
said semipolar plane is a plane inclined by at least about 10 degrees and not more than about 70 degrees with respect to a (0001) plane or a (000-1) plane.

12. The semiconductor laser device according to claim 7, wherein
each of said blue semiconductor laser element and said green semiconductor laser element further include a waveguide extending in a direction obtained by projecting a [0001] direction onto the major surface of said semipolar plane.

13. The semiconductor laser device according to claim 3, wherein
said blue semiconductor laser element includes a third active layer made of a nitride-based semiconductor formed on the surface of said substrate and having a major surface of a nonpolar plane, and
said green semiconductor laser element includes a fourth active layer made of a nitride-based semiconductor formed on the surface of said substrate and having a major surface of a surface orientation substantially identical to said nonpolar plane.

14. The semiconductor laser device according to claim 13, wherein
said third active layer has a quantum well structure having a third well layer made of InGaN, while said fourth active layer has a quantum well structure having a fourth well layer made of InGaN, and
the thickness of said third well layer is larger than the thickness of said fourth well layer.

15. The semiconductor laser device according to claim 13, wherein
said nonpolar plane is a substantially (11-22) plane.

16. The semiconductor laser device according to claim 13, wherein
the major surface of said substrate has a surface orientation substantially identical to said nonpolar plane.

17. The semiconductor laser device according to claim 3, wherein
said blue semiconductor laser element is formed on a surface of one side of said substrate and constituted of a fifth active layer, a first semiconductor layer and a first electrode successively stacked from the side of said substrate,
said green semiconductor laser element is so formed as to adjacently align with said blue semiconductor laser element and constituted of a sixth active layer, a second semiconductor layer and a second electrode successively stacked from the side of said substrate,
the semiconductor laser device further comprises a support base formed on said first electrode through a first fusion layer and formed on said second electrode through a second fusion layer,
said substrate has a surface of another side on a side opposite to said one side, and
the semiconductor laser device has a relation of t3 t4 when t1<t2 and has a relation of t3<t4 when t1>t2, where t1, t2, t3 and t4 represent the thickness of said blue semiconductor laser element from the side of said another side to a surface of said first semiconductor layer on said one side, the thickness of said green semiconductor laser element from the side of said another side to a surface of said second semiconductor layer on said one side, the thickness of said first electrode and the thickness of said second electrode, respectively.

18. The semiconductor laser device according to claim 17, wherein
said first electrode consists of a first pad electrode, and said second electrode consists of a second pad electrode.

19. The semiconductor laser device according to claim 18, wherein
the thickness of said first pad electrode is larger than the thickness of said second pad electrode in a case of t3>t4, and the thickness of said second pad electrode is larger than the thickness of said first pad electrode in a case of t3<t4.

20. A display comprising:
a semiconductor laser device comprising:
a green semiconductor laser element having one or a plurality of laser beam emitting portions,
a blue semiconductor laser element having one or a plurality of laser beam emitting portions, and
a red semiconductor laser element having one or a plurality of laser beam emitting portions, wherein
at least two semiconductor laser elements among said green semiconductor laser element, said blue semiconductor laser element and said red semiconductor laser element have such a relation that the number of said laser beam emitting portions of said semiconductor laser element whose total output power is relatively small is larger than the number of said laser beam emitting portions of said semiconductor laser element, having said plurality of laser beam emitting portions, whose total output power is relatively large, or the number of said semiconductor laser element, having one said laser beam emitting portion, whose output power is relatively large; and
modulation means modulating beams from said semiconductor laser device.
